(19) United States
(12) Patent Application Publication
(10) Pub. No.: US 2020/0409420 A1
(43) Pub. Date: Dec. 31, 2020

(54) FUNCTIONAL PANEL, SEMICONDUCTOR DEVICE, DISPLAY DEVICE, INPUT/OUTPUT DEVICE, DATA PROCESSING DEVICE

(71) Applicant: SEMICONDUCTOR ENERGY LABORATORY CO., LTD., Atsugi-shi (JP)

(72) Inventors: Daiki NAKAMURA, Atsugi (JP); Hiroki ADACHI, Tochigi (JP); Junpei YANAKA, Tochigi (JP)

(73) Assignee: SEMICONDUCTOR ENERGY LABORATORY CO., LTD., Atsugi-shi (JP)

(21) Appl. No.: 16/904,874

(22) Filed: Jun. 18, 2020

(30) Foreign Application Priority Data
Jun. 28, 2019 (JP) 2019-121280

(51) Int. Cl. G06F 1/16; G09F 9/30; G06F 1/18; H01L 51/00; G09G 3/3275; G06F 3/041

(52) U.S. Cl. CPC G06F 1/1652; G09F 9/301; G06F 1/189; G09G 2380/02; G09G 3/3275; G06F 3/0416; H01L 51/0097

(57) ABSTRACT

To provide a novel functional panel that is highly convenient, useful, or reliable. The functional panel includes a first region, a second region, and a third region. The third region is positioned between the first region and the second region, can be bent, and includes a functional layer, a bonding layer, and a first conductive film. The bonding layer includes a region positioned between the functional layer and the first conductive film. The functional layer includes a circuit and an insulating film. The circuit includes a second conductive film. The insulating film includes a region positioned between the first conductive film and the second conductive film. A capacitor is formed between the first conductive film and the second conductive film.

### BACKGROUND OF THE INVENTION

### 1. Field of the Invention

One embodiment of the present invention relates to a functional panel, a display device, an input/output device, a data processing device, or a semiconductor device.

Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Specific examples of the technical field of one embodiment of the present invention disclosed in this specification include a semiconductor device, a display device, a light-emitting device, a power storage device, a memory device, a method of driving any of them, and a method of manufacturing any of them.

### 2. Description of the Related Art

A display panel that includes a first region, a second region, and a display region is known (Patent Document 1). The second region contains part of the display region and includes a first member. The second region can be curved such that the first member faces the outside. The first member includes a first elastic body and a second elastic body. The second elastic body includes an end portion that is partly or entirely covered with the first elastic body. The second elastic body has a higher modulus of elasticity than the first elastic body.

### REFERENCE

[Patent Document 1] PCT International Publication No. 2019/106480

### SUMMARY OF THE INVENTION

An object of one embodiment of the present invention is to provide a novel functional panel that is highly convenient, useful, or reliable. Another object is to provide a novel semiconductor device that is highly convenient, useful, or reliable. Another object is to provide a novel input/output device that is highly convenient, useful, or reliable. Another object is to provide a novel data processing device that is highly convenient, useful, or reliable. Another object is to provide a novel functional panel, a novel input/output device, a novel data processing device, or a novel semiconductor device.

Note that the description of these objects does not preclude the existence of other objects. One embodiment of the present invention does not have to achieve all these objects. Other objects will be apparent from and can be derived from the description of the specification, the drawings, the claims, and the like.

(1) One embodiment of the present invention is a functional panel including a first region, a second region, and a third region.

The third region is positioned between the first region and the second region, can be bent, and includes a functional layer, a bonding layer, and a first conductive film.

The bonding layer includes a region positioned between the functional layer and the first conductive film. The functional layer includes a circuit and an insulating film.

The circuit includes a second conductive film. The insulating film includes a region positioned between the first conductive film and the second conductive film.

A capacitor is formed between the first conductive film and the second conductive film.

Thus, with the use of the first conductive film, the circuit can be shielded from a noise. Furthermore, the circuit can operate stably. As a result, a novel functional panel that is highly convenient, useful, or reliable can be provided. Note that in this specification and the like, an electromagnetic noise caused by electrostatic discharge or the like is simply referred to as a noise.

(2) Another embodiment of the present invention is the above-described functional panel further including a first base. Note that the first base includes a region where the first conductive film is positioned between the bonding layer and the first base.

Thus, the first conductive film can be protected from an external force or the like with the use of the first base. Thus, a novel functional panel that is highly convenient, useful, or reliable can be provided.

(3) Another embodiment of the present invention is the above-described functional panel further including a fourth region and a fifth region.

The fifth region is positioned between the first region and the fourth region, and has a first flexural rigidity.

The third region includes a second base. The second base includes a region where the first conductive film is positioned between the bonding layer and the second base. The third region has a second flexural rigidity.

The second flexural rigidity is higher than the first flexural rigidity.

Thus, a neutral plane of the third region can be close to the second base. Alternatively, the neutral plane of the third region can be closer to the second base than a neutral plane of the fifth region is. Alternatively, the third region can be bent such that the conductive films are on the outer side than the functional layer, with the center of a circle of curvature that appears at the bending as the reference. Alternatively, for example, a tensile stress applied to the second conductive film when the third region is bent in the above manner can be reduced. Alternatively, for example, compressive stress that is caused by the above bending can be applied to the second conductive film. Alternatively, for example, a breakdown of the functional layer which is caused by the above bending can be prevented. Thus, a novel functional panel that is highly convenient, useful, or reliable can be provided.

(4) Another embodiment of the present invention is the above-described functional panel. The third region can be bent such that the conductive film is on the outer side than the functional layer, with the center of a circle of curvature that appears at the bending as the reference, and the fifth region can be bent in a direction opposite to the bending direction of the third region.

Thus, the third region and the fifth region can be bent in alternate directions. Alternatively, the functional panel can be bent in a zigzag manner, for example. Alternatively, for example, a breakdown of the functional layer caused by the zigzag bending can be prevented. Alternatively, for example, the fifth region can be bent such that the conductive film is on the inner side than the functional layer, with the center of a circle of curvature that appears at the bending as the reference. Thus, a novel functional panel that is highly convenient, useful, or reliable can be provided.

(5) Another embodiment of the present invention is any of the above-described functional panels further including a pixel. The circuit includes a first pixel circuit.

The pixel includes a light-emitting element and the first pixel circuit. The light-emitting element is electrically connected to the first pixel circuit.

Thus, with the use of the first conductive film, the pixel is shielded, whereby transmission of a noise can be prevented. Alternatively, the adverse effect of a noise on display can be reduced. Alternatively, disturbance of display caused by bending can be reduced. Alternatively, disturbance of display caused by an approach of a finger or the like can be reduced. Thus, a novel functional panel that is highly convenient, useful, or reliable can be provided.

(6) Another embodiment of the present invention is the above-described functional panel further including a pair of pixels.

The pair of pixels includes the above-described pixel and another pixel. The other pixel includes a second pixel circuit and a photoelectric conversion element.

The photoelectric conversion element is electrically connected to the second pixel circuit.

(7) Another embodiment of the present invention is the above-described functional panel further including a functional layer.

The functional layer includes a first pixel circuit. The first pixel circuit includes a first transistor. The functional layer includes a second pixel circuit. The second pixel circuit includes a second transistor. The functional layer includes a driver circuit. The driver circuit includes a third transistor.

The first transistor includes a semiconductor film. The second transistor includes a semiconductor film that can be formed in a step of forming the semiconductor film of the first transistor. The third transistor includes a semiconductor film that can be formed in the step of forming the semiconductor film of the first transistor.

Thus, the pixel circuit can be formed in the functional layer. Alternatively, the driver circuit can be formed in the functional layer. Alternatively, for example, a semiconductor film that is used for the driver circuit can be formed in a step of forming the semiconductor film in the pixel circuit. Alternatively, the manufacturing process of the functional panel can be simplified. Thus, a novel functional panel that is highly convenient, useful, or reliable can be provided.

(8) Another embodiment of the present invention is a semiconductor device including any of the above-described functional panels and a housing.

The housing includes a first plane, a second plane, and a third plane.

The third plane is positioned between the first plane and the second plane. The first plane overlaps with the first region. The second plane overlaps with the second region. A distance is provided between the third plane and the third region. Note that the distance is changed by bending of the third region.

Thus, the circuit can operate stably even when the distance between the housing and the circuit is changed by bending of the third region. Alternatively, the first conductive film can be protected from an external force or the like with the use of the first base. Thus, a novel semiconductor device that is highly convenient, useful, or reliable can be provided.

(9) Another embodiment of the present invention is a display device including the above-described functional panel and a control portion.

The control portion is supplied with image data and control data, generates data on the basis of the image data, generates a control signal on the basis of the control data, and supplies the data and the control signal

The functional panel is supplied with the data and the control signal. The pixel emits light on the basis of the data.

Accordingly, the image data can be displayed using the light-emitting element. Consequently, a novel display device that is highly convenient, useful, or reliable can be provided.

(10) Another embodiment of the present invention is an input/output device including an input portion and a display portion.

The display portion includes the above functional panel. The input portion includes a sensing region and senses an object approaching the sensing region. The sensing region includes a region overlapping with the pixel.

Accordingly, an object that approaches the region overlapping with the display portion can be sensed while image data is displayed using the display portion. Alternatively, a finger or the like that approaches the display portion can be used as a pointer to input positional data. Alternatively, positional data can be associated with image data displayed on the display portion. Consequently, a novel input/output device that is highly convenient, useful, or reliable can be provided.

(11) Another embodiment of the present invention is a data processing device including an arithmetic device and an input/output device.

The arithmetic device is supplied with input data or sensing data. The arithmetic device generates control data and image data on the basis of the input data or the sensing data. The arithmetic device supplies the control data and the image data.

The input/output device supplies the input data and the sensing data. The input/output device is supplied with the control data and the image data. The input/output device includes a display portion, an input portion, and a sensor portion.

The display portion includes the above functional panel. The display portion displays the image data on the basis of the control data.

The input portion generates the input data, and the sensor portion generates the sensing data.

Accordingly, the control data can be generated on the basis of the input data or the sensing data. Alternatively, the image data can be displayed on the basis of the input data or the sensing data. Consequently, a novel data processing device that is highly convenient, useful, or reliable can be provided.

(12) Another embodiment of the present invention is a data processing device including the above functional panel and at least one of a keyboard, a hardware button, a pointing device, a touch sensor, an illuminance sensor, an imaging device, an audio input device, an eye-gaze input device, and an attitude sensing device.

The above structure allows the arithmetic device to generate image data or control data on the basis of data supplied using a variety of input devices. Consequently, a novel data processing device that is highly convenient, useful, or reliable can be provided.

Although the block diagram attached to this specification shows components classified by their functions in independent blocks, it is difficult to classify actual components according to their functions completely, and it is possible for one component to have a plurality of functions.

In this specification, the terms “source” and “drain” of a transistor interchange with each other depending on the polarity of the transistor or the levels of potentials applied to the terminals. In general, in an n-channel transistor, a terminal to which a lower potential is applied is called a source, and a terminal to which a higher potential is applied is called a drain. In a p-channel transistor, a terminal to which a lower potential is applied is called a drain, and a terminal to which a higher potential is applied is called a source. In this specification, the connection relation of a transistor is sometimes described assuming for convenience that the source and the drain are fixed; in reality, the names of the source and the drain interchange with each other depending on the relation of the potentials.

In this specification, a “source” of a transistor means a source region that is part of a semiconductor film functioning as an active layer or a source electrode connected to the semiconductor film. Similarly, a “drain” of a transistor means a drain region that is part of the semiconductor film or a drain electrode connected to the semiconductor film. A “gate” means a gate electrode.

In this specification, a state in which transistors are connected to each other in series means, for example, a state in which only one of a source and a drain of a first transistor is connected to only one of a source and a drain of a second transistor. In addition, a state in which transistors are connected in parallel means a state in which one of a source and a drain of a first transistor is connected to one of a source and a drain of a second transistor and the other of the source and the drain of the first transistor is connected to the other of the source and the drain of the second transistor.

In this specification, the term “connection” means electrical connection and corresponds to a state where current, voltage, or a potential can be supplied or transmitted. Accordingly, connection means not only direct connection but also indirect connection through a circuit element such as a wiring, a resistor, a diode, or a transistor that allows current, voltage, or a potential to be supplied or transmitted.

In this specification, even when different components are connected to each other in a circuit diagram, there is actually a case where one conductive film has functions of a plurality of components, such as a case where part of a wiring serves as an electrode. The term “connection” in this specification also means such a case where one conductive film has functions of a plurality of components.

In this specification, one of a first electrode and a second electrode of a transistor refers to a source electrode and the other refers to a drain electrode.

According to one embodiment of the present invention, a novel functional panel that is highly convenient, useful, or reliable can be provided. A novel semiconductor device that is highly convenient, useful, or reliable can be provided. A novel input/output device that is highly convenient, useful, or reliable can be provided. A novel data processing device that is highly convenient, useful, or reliable can be provided. A novel functional panel, a novel input/output device, a novel data processing device, or a novel semiconductor device can be provided.

Note that the description of these effects does not preclude the existence of other effects. One embodiment of the present invention does not necessarily achieve all the effects listed above. Other effects will be apparent from and can be derived from the description of the specification, the drawings, the claims, and the like.

### BRIEF DESCRIPTION OF THE DRAWINGS

FIGS. 1A to 1C illustrate a structure of a functional panel of one embodiment.

FIGS. 2A and 2B are cross-sectional views illustrating a functional panel of one embodiment.

FIG. 3 is a cross-sectional view illustrating a structure of a functional panel of one embodiment.

FIGS. 4A to 4C are cross-sectional views each illustrating a functional panel of one embodiment.

FIGS. 5A to 5C illustrate a display device of one embodiment.

FIGS. 6A to 6C illustrate a display device of one embodiment.

FIGS. 7A and 7B are cross-sectional views illustrating a display device of one embodiment.

FIGS. 8A and 8B illustrate a functional panel of one embodiment.

FIGS. 9A to 9C illustrate a structure of a functional panel of one embodiment.

FIG. 10 is a circuit diagram illustrating a functional panel of one embodiment.

FIG. 11 is a circuit diagram illustrating a functional panel of one embodiment.

FIG. 12 is a cross-sectional view illustrating a functional panel of one embodiment.

FIGS. 13A and 13B are cross-sectional views illustrating a functional panel of one embodiment.

FIGS. 14A and 14B are cross-sectional views illustrating a functional panel of one embodiment.

FIGS. 15A and 15B are cross-sectional views illustrating a functional panel of one embodiment.

FIG. 16 illustrates a functional panel of one embodiment.

FIGS. 17A and 17B are circuit diagrams illustrating a functional panel of one embodiment.

FIG. 18 illustrates operation of a functional panel of one embodiment.

FIGS. 19A to 19D illustrate structures of display devices of embodiments.

FIG. 20 is a block diagram illustrating a structure of an input/output device of one embodiment.

FIGS. 21A to 21D illustrate a structure of an input/output device of one embodiment.

FIGS. 22A to 22D illustrate a structure of an input/output device of one embodiment.

FIGS. 23A to 23C are a block diagram and projection views illustrating structures of data processing devices of embodiments.

FIGS. 24A and 24B are flow charts illustrating a method of driving a data processing device of one embodiment.

FIGS. 25A to 25C illustrate a method of driving a data processing device of one embodiment.

FIGS. 26A to 26C illustrate a method of driving a data processing device of one embodiment.

FIGS. 27A to 27E illustrate structures of data processing devices of one embodiment.

FIGS. 28A to 28E illustrate structures of data processing devices of one embodiment.

FIGS. 29A and 29B illustrate structures of data processing devices of embodiments.

FIG. 30 is a cross-sectional view illustrating a structure of a functional panel of one embodiment.

### DETAILED DESCRIPTION OF THE INVENTION

A functional panel of one embodiment of the present invention includes a first region, a second region, and a third region. The third region is positioned between the first region and the second region, can be bent, and includes a functional layer, a bonding layer, and a first conductive film. The bonding layer includes a region positioned between the functional layer and the first conductive film. The functional layer includes a circuit and an insulating film. The circuit includes a second conductive film. The insulating film includes a region positioned between the first conductive film and the second conductive film. A capacitor is formed between the first conductive film and the second conductive film.

Thus, with the use of the first conductive film, the circuit can be shielded from a noise. Alternatively, the circuit can operate stably. Thus, a novel functional panel that is highly convenient, useful, or reliable can be provided.

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments. Note that in structures of the invention described below, the same portions or portions having similar functions are denoted by the same reference numerals in different drawings, and the description thereof is not repeated.

### Embodiment 1

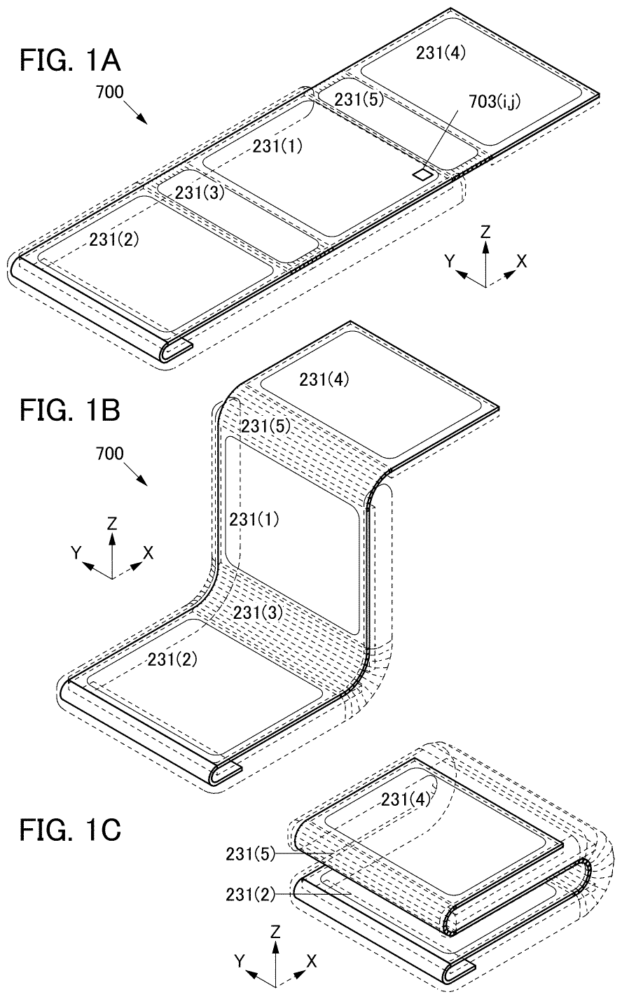

In this embodiment, a structure of a functional panel of one embodiment of the present invention will be described with reference to FIGS. 1A to 1C, FIGS. 2A and 2B, FIG. 3, FIGS. 4A to 4C, and FIG. 30.

FIGS. 1A to 1C illustrate a structure of a functional panel of one embodiment of the present invention. FIG. 1A is a perspective view of the functional panel of one embodiment of the present invention. FIGS. 1B and 1C each illustrate the functional panel in FIG. 1A that is partly bent.

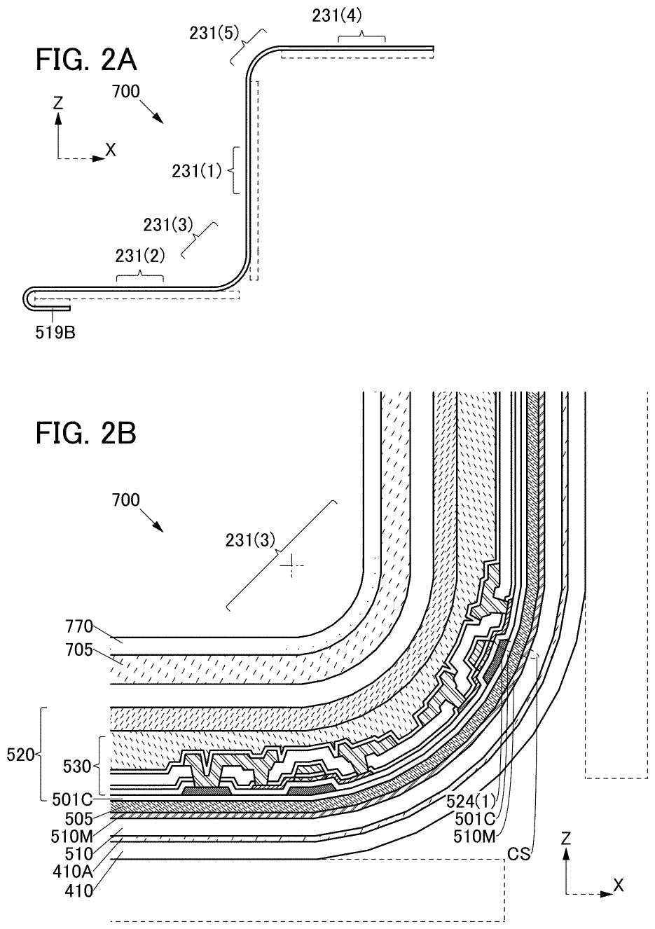

FIGS. 2A and 2B illustrate a structure of the functional panel of one embodiment of the present invention. FIG. 2A is a cross-sectional view of the functional panel of one embodiment of the present invention illustrated in FIG. 1B. FIG. 2B illustrates part of FIG. 2A.

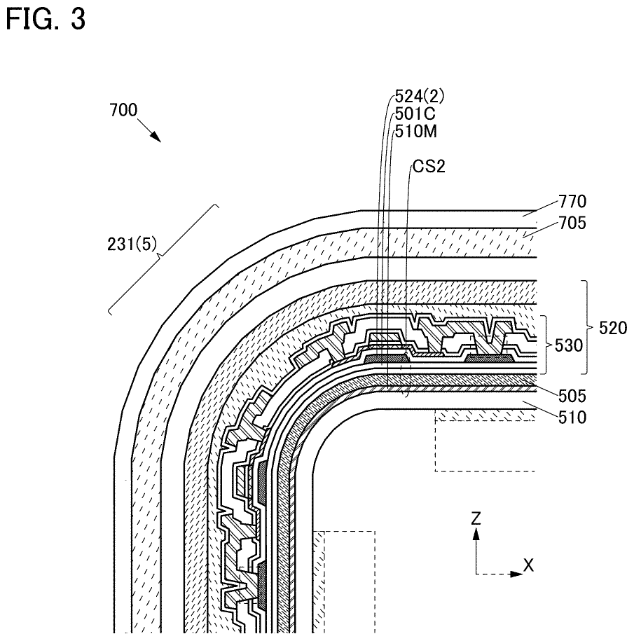

FIG. 3 illustrates a structure of the functional panel of one embodiment of the present invention. FIG. 3 is a cross-sectional view of the functional panel of one embodiment of the present invention illustrated in FIG. 1B, and illustrates part of FIG. 2A.

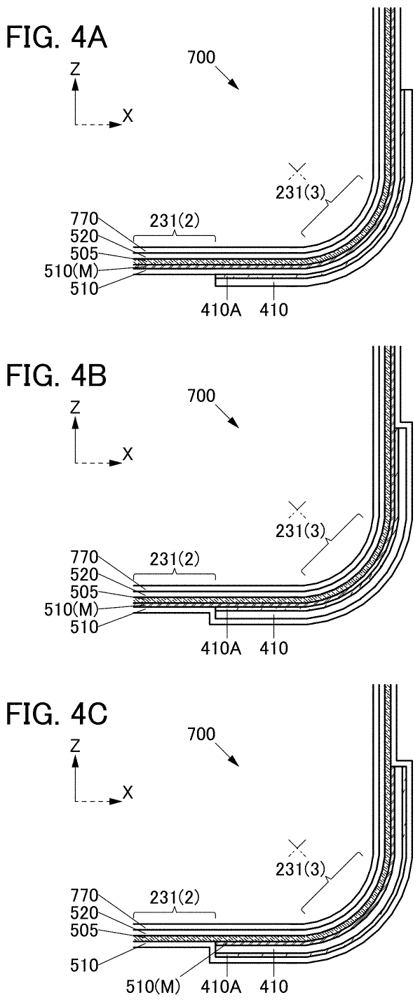

FIGS. 4A to 4C illustrate structures of the functional panel of one embodiment of the present invention. FIG. 4A is a cross-sectional view of the functional panel of one embodiment of the present invention illustrated in FIG. 2B. FIGS. 4B and 4C illustrate structures different from the structure of FIG. 4A.

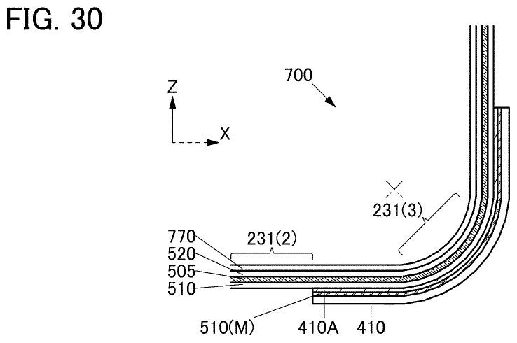

FIG. 30 illustrates a structure of a functional panel of one embodiment of the present invention. FIG. 30 illustrates a structure different from the structures of FIGS. 4A to 4C.

Note that in this specification, an integer variable of 1 or more may be used for reference numerals. For example, “(p)” where p is an integer variable of 1 or more may be used for part of a reference numeral that specifies any one of components (p components at a maximum). For another example, “(m,n)” where each of m and n is an integer variable of 1 or more may be used for part of a reference numeral that specifies any one of components (m×n components at a maximum).

### <Structure Example 1 of Functional Panel 700>

The functional panel described in this embodiment includes a region 231(1), a region 231(2), and a region 231(3) (see FIGS. 1A to 1C).

### <<Structure Example 1 of Region 231(3)>>

The region 231(3) is positioned between the region 231(1) and the region 231(2) (see FIG. 1B and FIG. 2A). The region 231(3) can be bent.

The region 231(3) includes a functional layer 520, a bonding layer 505, and a conductive film 510M (see FIG. 2B).

### [Structure Example of Bonding Layer 505]

The bonding layer 505 includes a region positioned between the functional layer 520 and the conductive film 510M. For example, the bonding layer 505 has a function of bonding the functional layer 520 and the conductive film 510M. Specifically, the functional layer 520 and the conductive film 510M which is formed over another base in advance can be bonded to each other with the bonding layer 505.

An inorganic material, an organic material, a composite material of an inorganic material and an organic material, or the like can be used for the bonding layer 505.

For example, an organic material such as a resin having thermal fusibility or a curable resin can be used for the bonding layer 505.

For example, an organic material such as a reactive curable adhesive, a photo-curable adhesive, a thermosetting adhesive, and/or an anaerobic adhesive can be used for the bonding layer 505.

Specifically, an adhesive containing an epoxy resin, an acrylic resin, a silicone resin, a phenol resin, a polyimide resin, an imide resin, a polyvinyl chloride (PVC) resin, a polyvinyl butyral (PVB) resin, an ethylene vinyl acetate (EVA) resin, or the like can be used for the bonding layer 505.

### <<Structure Example 1 of Functional Layer 520>>

The functional layer 520 includes a circuit 530 and an insulating film 501C.

### <<Structure Example 1 of Circuit 530>>

The circuit 530 includes a conductive film 524(1). For example, a transistor can be used in the circuit 530. Furthermore, a conductive film can be used for a gate electrode, a source electrode, or a drain electrode of the transistor. Specifically, the conductive film 524(1) can be used for the gate electrode.

### <<Structure Example 1 of Insulating Film 501C>>

The insulating film 501C includes a region positioned between the conductive film 510M and the conductive film 524(1). For example, a material containing silicon and oxygen, polyimide, or the like can be used for the insulating film 501C. Thus, a short circuit between the circuit 530 and the conductive film 510M can be prevented, for example.

### <<Structure Example 1 of Conductive Film 510M>>

A capacitor CS is formed between the conductive film 510M and the conductive film 524(1). For example, an inorganic conductive material, an organic conductive material, metal, a conductive ceramic material, or the like can be used for the conductive film 510M. Specifically, a material that can be used for a wiring, such as aluminum or titanium, can be used. The conductive film 510M can be formed into a film shape by an evaporation method or a printing method.

Thus, with the use of the conductive film 510M, the circuit 530 can be shielded from a noise. Thus, a novel functional panel that is highly convenient, useful, or reliable can be provided.

### <Structure Example 2 of Functional Panel 700>

The functional panel 700 of one embodiment of the present invention includes a base 510.

### <<Structure Example 1 of Base 510>>

The base 510 includes a region where the conductive film 510M is positioned between the bonding layer 505 and the base 510. For example, a flexible material can be used for the base 510.

Thus, the conductive film 510M can be protected from an external force with the use of the base 510. Alternatively, the conductive film 510M can be protected from friction caused by the bending. Thus, a novel functional panel that is highly convenient, useful, or reliable can be provided.

### <Structure Example 3 of Functional Panel 700>

The functional panel 700 of one embodiment of the present invention includes a region 231(4) and a region 231(5).

### <<Structure Example 1 of Region 231(5)>>

The region 231(5) is positioned between the region 231(1) and the region 231(4) (see FIGS. 1A and 1B and FIG. 2A).

The region 231(5) has a flexural rigidity EI(5).

### <<Structure Example 2 of Region 231(3)>>

The region 231(3) includes a base 410, and the base 410 includes a region where the conductive film 510M is positioned between the bonding layer 505 and the base 410 (see FIG. 2B, FIG. 4A, and FIG. 30). For example, a bonding layer 410A can be used to bond the base 410 and the base 510.

The region 231(3) may include a region where the base 410 is positioned between the conductive film 510M and the base 510 (FIG. 4B or FIG. 4C).

The region 231(3) has a flexural rigidity EI(3). The flexural rigidity EI(3) is higher than the flexural rigidity EI(5).

Thus, a neutral plane of the region 231(3) can be close to the base 410. Alternatively, the neutral plane of the region 231(3) can be closer to the base 410 than a neutral plane of the region 231(5) is. Alternatively, the region 231(3) can be bent such that the conductive film 510M is on the outer side than the functional layer 520, with the center of a circle of curvature that appears at the bending as the reference. Alternatively, for example, a tensile stress applied to the conductive film 524(1) when the region 231(3) is bent in the above manner can be reduced. Alternatively, for example, compressive stress that is caused by the above bending can be applied to the conductive film 524(1). Alternatively, for example, a breakdown of the functional layer 520 which is caused by the above bending can be prevented. Thus, a novel functional panel that is highly convenient, useful, or reliable can be provided.

### <<Structure Example 1 of Region 231>>

The region 231(3) is bent such that the conductive film 510M is on the outer side than the functional layer 520, with the center of a circle of curvature that appears at the bending as the reference. The region 231(5) can bent in the direction opposite to the direction in which the region 231(3) is bent (see FIGS. 2A and 2B and FIG. 3).

Thus, the region 231(3) and the region 231(5) can be bent in alternate directions. Alternatively, the functional panel can be bent in a zigzag manner, for example. Alternatively, the functional layer 520 can be prevented from being broken due to the zigzag bending, for example. Alternatively, for example, the region 231(5) can be bent such that the conductive film 510M is on the inner side than the functional layer 520, with the center of a circle of curvature that appears at the bending as the reference. Thus, a novel functional panel that is highly convenient, useful, or reliable can be provided.

<Structure Example 4 of functional panel 700>

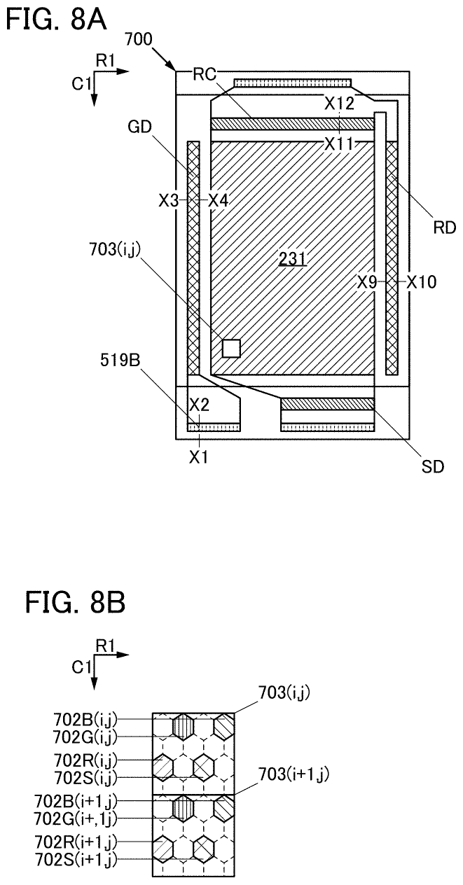

The functional panel 700 of one embodiment of the present invention includes a pixel 702G(i,j). Note that the functional panel 700 includes a pixel 703(i,j), and the pixel 703(i,j) includes the pixel 702G(i,j) (see FIG. 1A and FIGS. 8A and 8B).

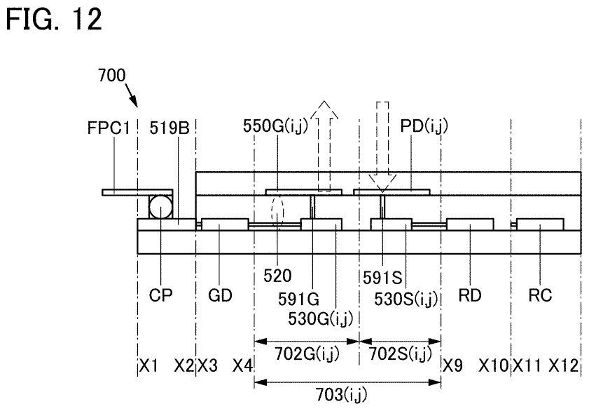

The circuit 530 includes a pixel circuit 530G(i,j) (see FIG. 12).

### <<Structure Example 1 of Pixel 702G(i,j)>>

The pixel 702G(i,j) includes a light-emitting element 550G(i,j) and the pixel circuit 530G(i,j).

The light-emitting element 550G(i,j) is electrically connected to the pixel circuit 530G(i,j).

Thus, with the use of the conductive film 510M, the pixel 702G(i,j) is shielded, whereby transmission of a noise can be prevented. Alternatively, the adverse effect of a noise on display can be reduced. Alternatively, disturbance of display caused by bending can be reduced. Alternatively, disturbance of display caused by an approach of a finger or the like can be reduced. Thus, a novel functional panel that is highly convenient, useful, or reliable can be provided.

Note that this embodiment can be combined with any of the other embodiments in this specification as appropriate.

### Embodiment 2

In this embodiment, a structure of a functional panel of one embodiment of the present invention will be described with reference to FIGS. 8A and 8B, FIGS. 9A to 9C, FIG. 10, and FIG. 11.

FIGS. 8A and 8B illustrate a structure of a functional panel of one embodiment of the present invention. FIG. 8A is a top view illustrating the structure of the functional panel of one embodiment of the present invention, and FIG. 8B illustrates part of FIG. 8A.

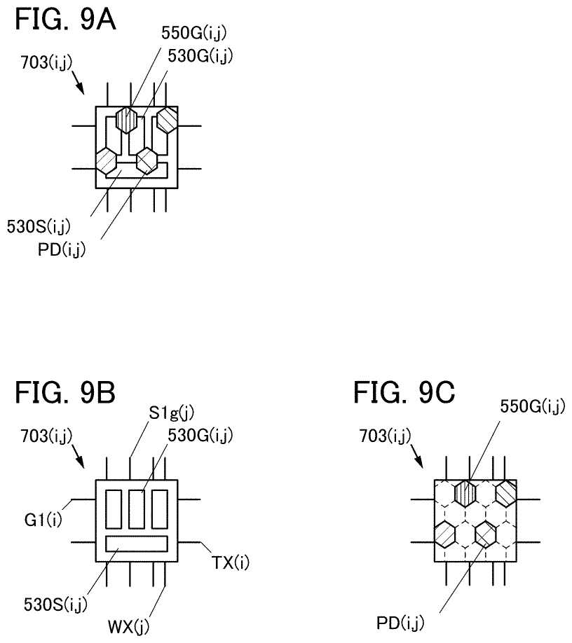

FIG. 9A illustrates part of FIG. 8A, FIG. 9B illustrates part of FIG. 9A, and FIG. 9C illustrates part of FIG. 9A.

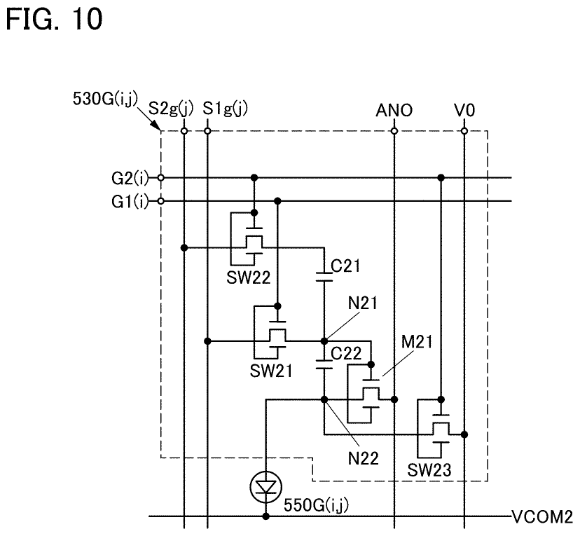

FIG. 10 illustrates a structure of a functional panel of one embodiment of the present invention. Specifically, FIG. 10 illustrates a configuration of a pixel circuit.

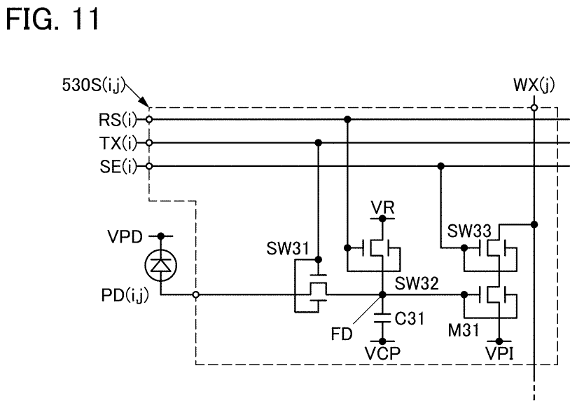

FIG. 11 illustrates a structure of a functional panel of one embodiment of the present invention. Specifically, FIG. 11 is a circuit diagram illustrating a configuration of a pixel circuit in the functional panel of one embodiment of the present invention.

### <Structure Example 1 of Functional Panel 700>

The functional panel 700 includes a set of pixels 703(i,j) (see FIG. 8A).

<<Structure Example 1 of Pixel 703(i,j)>>

The set of pixels 703(i,j) includes the pixel 702G(i,j) (see FIG. 8B). The pixel 702G(i,j) includes a pixel circuit 530G(i,j) and the light-emitting element 550G(i,j), and the light-emitting element 550G(i,j) is electrically connected to the pixel circuit 530G(i,j) (see FIG. 9A).

### <<Structure Example 1 of Pixel Circuit 530G(i,j)>>

The pixel circuit 530G(i,j) includes a switch SW21, a switch SW22, a transistor M21, a capacitor C21, and a node N21 (see FIG. 10).

The transistor M21 includes a gate electrode electrically connected to the node N21, a first electrode electrically connected to the light-emitting element 550G(i,j), and a second electrode electrically connected to a conductive film ANO.

The switch SW21 includes a first terminal electrically connected to the node N21 and a second terminal electrically connected to a conductive film S1g(j). The switch SW21 has a function of controlling its on/off state on the basis of the potential of a conductive film G1(i).

The switch SW22 includes a first terminal electrically connected to a conductive film S2g(j), and has a function of controlling its on/off state on the basis of the potential of a conductive film G2(i).

The capacitor C21 includes a conductive film electrically connected to the node N21 and a conductive film electrically connected to a second electrode of the switch SW22.

Accordingly, an image signal can be stored in the node N21. Alternatively, the potential of the node N21 can be changed using the switch SW22. Alternatively, the intensity of light emitted from the light-emitting element 550G(i,j) can be controlled with the potential of the node N21. As a result, a novel functional panel that is highly convenient, useful, or reliable can be provided.

### <<Structure Example 1 of Light-Emitting Element 550G(i,j)>>

For example, an organic electroluminescent element, an inorganic electroluminescent element, a light-emitting diode, or a quantum-dot LED (QDLED) can be used as the light-emitting element 550G(i,j).

<<Structure Example 2 of Pixel Circuit 703(i,j)>>

The pixel 703(i,j) includes a pixel 702S(i,j) (see FIG. 8B). The pixel 702S(i,j) includes a pixel circuit 530S(i,j) and a photoelectric conversion element PD(i,j), and the photoelectric conversion element PD(i,j) is electrically connected to the pixel circuit 530S(i,j) (see FIG. 9A).

### <<Structure Example 1 of Pixel Circuit 530S(i,j)>>

The pixel circuit 530S(i,j) includes a switch SW31, a switch SW32, a switch SW33, a transistor M31, a capacitor C31, and a node FD (see FIG. 11).

The switch SW31 includes a first terminal electrically connected to the photoelectric conversion element PD(i,j), and a second terminal electrically connected to the node FD. The switch SW31 has a function of controlling its on/off state on the basis of the potential of a conductive film TX(i).

The switch SW32 includes a first terminal electrically connected to the node FD and a second terminal electrically connected to a conductive film VR. The switch SW32 has a function of controlling its on/off state on the basis of the potential of a conductive film RS(i).

The capacitor C31 includes a conductive film electrically connected to the node FD and a conductive film electrically connected to a conductive film VCP.

The transistor M31 includes a gate electrode electrically connected to the node FD and a first electrode electrically connected to a conductive film VPI.

The switch SW33 includes a first terminal electrically connected to a second electrode of the transistor M31, and a second terminal electrically connected to a conductive film WX(j). The switch SW33 has a function of controlling its on/off state on the basis of the potential of a conductive film SE(i).

Accordingly, an imaging signal generated by the photoelectric conversion element PD(i,j) can be transferred to the node FD using the switch SW31. Alternatively, an imaging signal generated by the photoelectric conversion element PD(i,j) can be stored in the node FD using the switch SW31. Alternatively, electrical continuity between the pixel circuit 530S(i,j) and the photoelectric conversion element PD(i,j) can be broken by the switch SW31. Alternatively, a correlated double sampling method can be used. Alternatively, noise in an imaging signal can be reduced. Thus, a novel functional panel that is highly convenient, useful, or reliable can be provided.

### <<Structure Example 1 of Photoelectric Conversion Element PD(i,j)>>

For example, a heterojunction photoelectric conversion element or a bulk heterojunction photoelectric conversion element can be used as the photoelectric conversion element PD(i,j).

<<Structure Example 3 of Pixel 703(i,j)>>

A plurality of pixels can be used in the pixel 703(i,j). For example, a plurality of pixels that show colors of different hues can be used. Note that a plurality of pixels can be referred to as subpixels. In addition, a set of subpixels can be referred to as a pixel.

Such a structure enables additive mixture or subtractive mixture of colors shown by the plurality of pixels. Alternatively, it is possible to express a color of a hue that an individual pixel cannot show.

Specifically, a pixel 702B(i,j) for showing blue, the pixel 702G(i,j) for showing green, and a pixel 702R(i,j) for showing red can be used in the pixel 703(i,j). The pixel 702B(i,j), the pixel 702G(i,j), and the pixel 702R(i,j) can each be referred to as a subpixel (see FIG. 8B).

As another example, a pixel for showing white or the like in addition to the above set can be used in the pixel 703(i,j). Moreover, a pixel for showing cyan, a pixel for showing magenta, and a pixel for showing yellow can be used in the pixel 703(i,j).

As another example, a pixel emitting infrared rays in addition to the above set can be used in the pixel 703(i,j). Specifically, a pixel that emits light including light with a wavelength of greater than or equal to 650 nm and less than or equal to 1000 nm can be used in the pixel 703(i,j).

Note that this embodiment can be combined with any of the other embodiments in this specification as appropriate.

### Embodiment 3

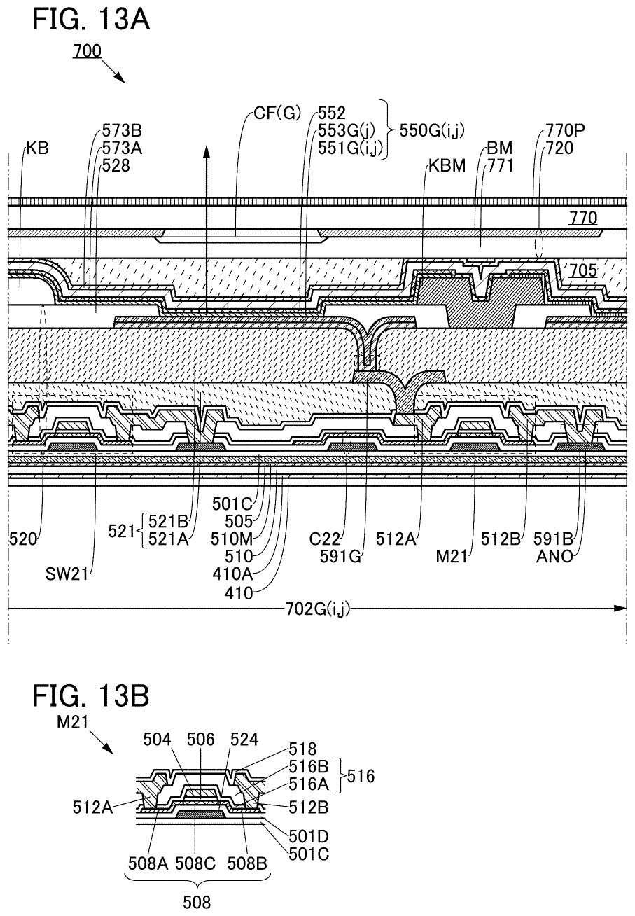

In this embodiment, a structure of a functional panel of one embodiment of the present invention will be described with reference to FIG. 12, FIGS. 13A and 13B, FIGS. 14A and 14B, and FIGS. 15A and 15B.

FIG. 12 illustrates a structure of a functional panel of one embodiment of the present invention. FIG. 12 shows a cross section of the pixel as well as cross sections along the lines X1-X2, X3-X4, X9-X10, and X11-X12 in FIG. 8A.

FIGS. 13A and 13B illustrate a structure of the functional panel of one embodiment of the present invention. FIG. 13A is a cross-sectional view of the pixel 702G(i,j) in FIG. 8B, and FIG. 13B is a cross-sectional view illustrating part of FIG. 13A.

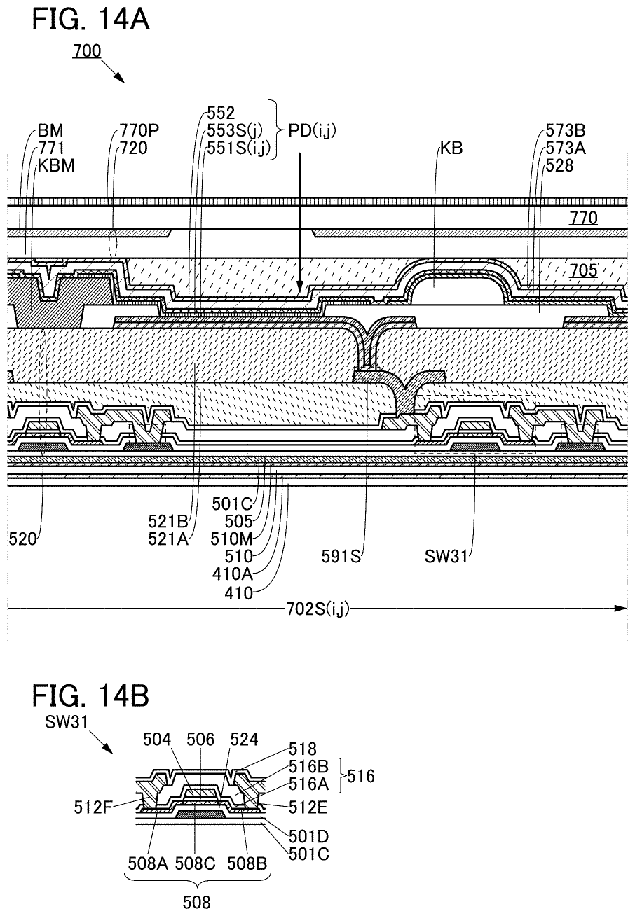

FIGS. 14A and 14B illustrate a structure of the functional panel of one embodiment of the present invention. FIG. 14A is a cross-sectional view of the pixel 702S(i,j) in FIG. 8B, and FIG. 14B is a cross-sectional view illustrating part of FIG. 14A.

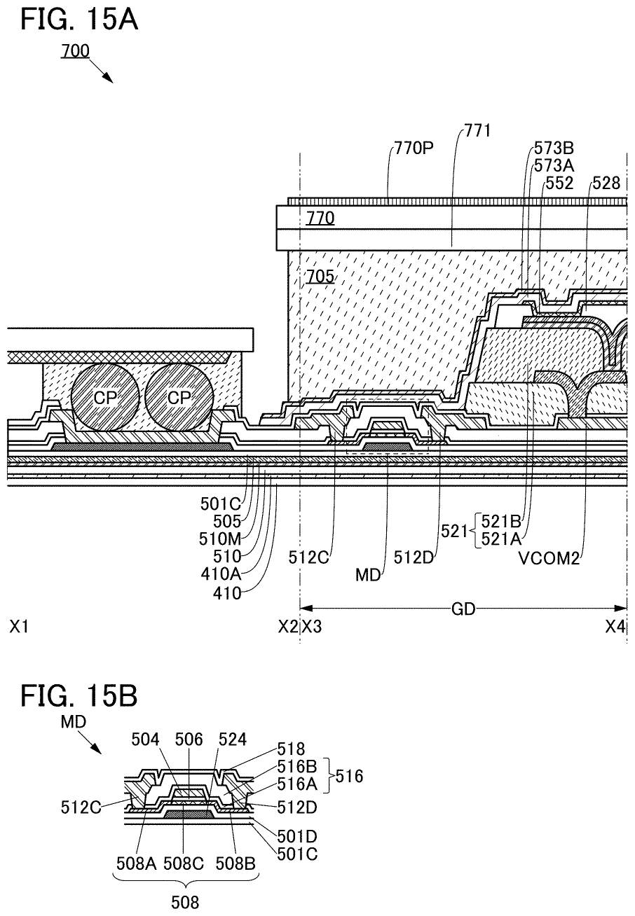

FIGS. 15A and 15B illustrate a structure of a functional panel of one embodiment of the present invention. FIG. 15A is a cross-sectional view along the lines X1-X2 and X3-X4 in FIG. 8A. FIG. 15B is a cross-sectional view illustrating part of FIG. 15A.

### <Structure Example 1 of Functional Panel 700>

A functional panel of one embodiment of the present invention includes a functional layer 520 (see FIG. 12).

### <<Structure Example 1 of Functional Layer 520>>

The functional layer 520 includes the pixel circuit 530G(i,j) (see FIG. 12). The functional layer 520 includes, for example, the transistor M21 used in the pixel circuit 530G(i,j) (see FIG. 10 and FIG. 13A).

The functional layer 520 has an opening 591G. The pixel circuit 530G(i,j) is electrically connected to the light-emitting element 550G(i,j) through the opening 591G (see FIG. 12 and FIG. 13A).

### <<Structure Example 2 of Functional Layer 520>>

The functional layer 520 includes the pixel circuit 530S(i,j) (see FIG. 12). The functional layer 520 includes, for example, a transistor used as the switch SW31 in the pixel circuit 530S(i,j) (see FIG. 12 and FIG. 14A).

The functional layer 520 has an opening 591S, and the pixel circuit 530S(i,j) is electrically connected to the photoelectric conversion element PD(i,j) through the opening 591S (see FIG. 12 and FIG. 14A).

Accordingly, the pixel circuit 530G(i,j) can be formed in the functional layer 520. Alternatively, the pixel circuit 530S(i,j) can be formed in the functional layer 520. Alternatively, for example, the semiconductor film used in the pixel circuit 530S(i,j) can be formed in the step of forming the semiconductor film used in the pixel circuit 530G(i,j). Alternatively, the process of manufacturing the functional panel can be simplified. As a result, a novel functional panel that is highly convenient, useful, or reliable can be provided.

### <<Structure Example 3 of Functional Layer 520>>

The functional layer 520 includes a driver circuit GD (see FIG. 8A and FIG. 12). The functional layer 520 includes, for example, the transistor MD used in the driver circuit GD (see FIG. 12 and FIG. 15A).

The functional layer 520 includes a driver circuit RD and a read circuit RC (see FIG. 12).

Accordingly, for example, the semiconductor film used in the driver circuit GD can be formed in the step of forming the semiconductor film used in the pixel circuit 530G(i,j). As another example, the semiconductor films used in the driver circuit RD and the read circuit RC can be formed in the step of forming the semiconductor film used in the pixel circuit 530G(i,j). Alternatively, the process of manufacturing the functional panel can be simplified. Thus, a novel functional panel that is highly convenient, useful, or reliable can be provided.

### <<Structure Example of Transistor>>

A bottom-gate transistor, a top-gate transistor, or the like can be used in the functional layer 520. Specifically, a transistor can be used as a switch.

The transistor includes a semiconductor film 508, a conductive film 504, a conductive film 512A, and a conductive film 512B (see FIG. 13B).

The semiconductor film 508 includes a region 508A electrically connected to the conductive film 512A and a region 508B electrically connected to the conductive film 512B. The semiconductor film 508 includes a region 508C between the region 508A and the region 508B.

The conductive film 504 includes a region overlapping with the region 508C and has a function of a gate electrode.

An insulating film 506 includes a region positioned between the semiconductor film 508 and the conductive film 504. The insulating film 506 has a function of a gate insulating film.

The conductive film 512A has one of a function of a source electrode and a function of a drain electrode, and the conductive film 512B has the other.

A conductive film 524 can be used in the transistor. The semiconductor film 508 is sandwiched between the conductive film 504 and a region of the conductive film 524. The conductive film 524 has a functions of a second gate electrode.

Note that in a step of forming the semiconductor film used in the transistor of the pixel circuit, the semiconductor film used in the transistor of the driver circuit can be formed.

### <<Structure Example 1 of Semiconductor Film 508>>

For example, a semiconductor including a Group 14 element can be used for the semiconductor film 508. Specifically, a semiconductor including silicon can be used for the semiconductor film 508.

### [Hydrogenated Amorphous Silicon]

For example, hydrogenated amorphous silicon can be used for the semiconductor film 508. Microcrystalline silicon or the like can also be used for the semiconductor film 508. Thus, it is possible to provide a functional panel having less display unevenness than a functional panel using polysilicon for the semiconductor film 508, for example. Alternatively, the size of the functional panel can be easily increased.

### [Polysilicon]

For example, polysilicon can be used for the semiconductor film 508. In this case, for example, the field-effect mobility of the transistor can be higher than that of a transistor using hydrogenated amorphous silicon for the semiconductor film 508. For another example, the driving capability can be higher than that of a transistor using hydrogenated amorphous silicon for the semiconductor film 508. For another example, the aperture ratio of the pixel can be higher than that in the case of employing a transistor using hydrogenated amorphous silicon for the semiconductor film 508.

For another example, the reliability of the transistor can be higher than that of a transistor using hydrogenated amorphous silicon for the semiconductor film 508.

The temperature required for manufacture of the transistor can be lower than that required for a transistor using single crystal silicon, for example.

The semiconductor film used in the transistor of the driver circuit can be formed in the same step as the semiconductor film used in the transistor of the pixel circuit. Alternatively, the driver circuit can be formed over a substrate where the pixel circuit is formed. Alternatively, the number of components included in an electronic device can be reduced.

### [Single Crystal Silicon]

For example, single crystal silicon can be used for the semiconductor film 508. In this case, for example, the resolution can be higher than that of a functional panel using hydrogenated amorphous silicon for the semiconductor film 508. Alternatively, a functional panel having less display unevenness than a functional panel using polysilicon for the semiconductor film 508, for example, can be provided. For another example, smart glasses or a head mounted display can be provided.

### <<Structure Example 2 of Semiconductor Film 508>>

For example, a metal oxide can be used for the semiconductor film 508. In this case, the pixel circuit can hold an image signal for a longer time than a pixel circuit including a transistor that uses amorphous silicon for the semiconductor film. Specifically, a selection signal can be supplied at a frequency of lower than 30 Hz, preferably lower than 1 Hz, further preferably less than once per minute while flickering is suppressed. Consequently, fatigue of a user of a data processing device can be reduced, and power consumption for driving can be reduced.

Moreover, the pixel circuit can hold an imaging signal for a longer time than a pixel circuit including a transistor that uses amorphous silicon for the semiconductor film. Specifically, the selection signal can be supplied at a frequency of lower than 30 Hz, preferably lower than 1 Hz, more preferably less than once per minute. Accordingly, images can be taken by a global shutter method. Furthermore, an image of an object in motion can be taken with little distortion.

For example, a transistor using an oxide semiconductor can be used. Specifically, an oxide semiconductor including indium or an oxide semiconductor including indium, gallium, and zinc can be used for the semiconductor film.

For example, a transistor having a lower leakage current in an off state than a transistor using amorphous silicon for a semiconductor film can be used. Specifically, a transistor using an oxide semiconductor for a semiconductor film can be used as a switch or the like. In that case, the potential of the floating node can be held for a longer time than in a circuit in which a transistor using amorphous silicon is used as a switch.

For example, a 25-nm-thick film including indium, gallium, and zinc can be used as the semiconductor film 508.

For example, a conductive film in which a 10-nm-thick film including tantalum and nitrogen and a 300-nm-thick film including copper are stacked can be used as the conductive film 504. The film including copper includes a region provided such that a film including tantalum and nitrogen is positioned between the film including copper and the insulating film 506.

For example, a stacked-layer film in which a 400-nm-thick film including silicon and nitrogen and a 200-nm-thick film including silicon, oxygen, and nitrogen are stacked can be used as the insulating film 506. The film including silicon and nitrogen includes a region provided such that the film including silicon, oxygen, and nitrogen is positioned between the film including silicon and nitrogen and the semiconductor film 508.

For example, a conductive film in which a 50-nm-thick film including tungsten, a 400-nm-thick film including aluminum, and a 100-nm-thick film including titanium are stacked in this order can be used as the conductive film 512A or the conductive film 512B. The film including tungsten includes a region in contact with the semiconductor film 508.

A manufacturing line for a bottom-gate transistor using amorphous silicon as a semiconductor, for example, can be easily remodeled into a manufacturing line for a bottom-gate transistor using an oxide semiconductor as a semiconductor. For another example, a manufacturing line for a top-gate transistor using polysilicon as a semiconductor can be easily remodeled into a manufacturing line for a top-gate transistor using an oxide semiconductor as a semiconductor. In any case, a conventional manufacturing line can be effectively utilized.

By using a metal oxide in the semiconductor film 508, display flickering can be suppressed. Alternatively, power consumption can be reduced, a moving image of high-speed motion can be displayed smoothly, or a photograph and the like can be displayed with a large number of gray levels. As a result, a novel functional panel that is highly convenient, useful, or reliable can be provided.

### <<Structure Example 3 of Semiconductor Film 508>>

For example, a compound semiconductor can be used as a semiconductor of the transistor. Specifically, a semiconductor including gallium arsenide can be used.

For example, an organic semiconductor can be used as a semiconductor of the transistor. Specifically, an organic semiconductor including any of polyacenes or graphene can be used for the semiconductor film.

### <<Structure Example of Capacitor>>

The capacitor includes one conductive film, another conductive film, and an insulating film. The insulating film includes a region positioned between these conductive films.

For example, the capacitor can include a conductive film used as the source electrode or the drain electrode of the transistor, a conductive film used as the gate electrode, and an insulating film used as the gate insulating film.

### <<Structure Example 2 of Functional Layer 520>>

The functional layer 520 includes an insulating film 521, an insulating film 518, an insulating film 516, the insulating film 506, an insulating film 501C, and the like (see FIGS. 13A and 13B).

The insulating film 521 includes a region positioned between the pixel circuit 530G(i,j) and the light-emitting element 550G(i,j).

The insulating film 518 includes a region positioned between the insulating film 521 and the insulating film 501C.

The insulating film 516 includes a region positioned between the insulating film 518 and the insulating film 501C.

The insulating film 506 includes a region positioned between the insulating film 516 and the insulating film 501C.

### [Insulating Film 521]

For example, an insulating inorganic material, an insulating organic material, or an insulating composite material including an inorganic material and an organic material can be used for the insulating film 521.

Specifically, an inorganic oxide film, an inorganic nitride film, an inorganic oxynitride film, and the like, or a layered material obtained by stacking some of these films can be used for the insulating film 521.

For example, a film including any of a silicon oxide film, a silicon nitride film, a silicon oxynitride film, an aluminum oxide film, and the like, or a film including a material obtained by stacking any of these films can be used for the insulating film 521. Note that a silicon nitride film is a dense film and has an excellent function of inhibiting diffusion of impurities.

For example, polyester, polyolefin, polyamide, polyimide, polycarbonate, polysiloxane, or an acrylic resin, or a layered or composite material including resins selected from these can be used for the insulating film 521. Note that polyimide is excellent in the following properties, for example, compared with other organic materials: thermal stability, an insulating property, toughness, a low dielectric constant, a low coefficient of thermal expansion, and high chemical resistance. Accordingly, polyimide is particularly suitable for the insulating film 521 or the like.

Alternatively, the insulating film 521 may be formed using a photosensitive material. Specifically, a film formed using photosensitive polyimide, a photosensitive acrylic resin, or the like can be used as the insulating film 521.

Accordingly, the insulating film 521 can reduce steps due to various components underlying the insulating film 521, for example.

### [Insulating Film 518]

For example, a material that can be used for the insulating film 521 can be used for the insulating film 518.

For example, a material that has a function of inhibiting diffusion of oxygen, hydrogen, water, alkali metal, alkaline earth metal, and the like can be used for the insulating film 518. Specifically, a nitride insulating film can be used as the insulating film 518. For example, silicon nitride, silicon nitride oxide, aluminum nitride, aluminum nitride oxide, or the like can be used for the insulating film 518. Thus, diffusion of impurities into the semiconductor film of the transistor can be inhibited.

### [Insulating Film 516]

For example, a material that can be used for the insulating film 521 can be used for the insulating film 516.

Specifically, a film formed by a method different from a method of forming the insulating film 518 can be used as the insulating film 516.

### [Insulating Film 506]

For example, a material that can be used for the insulating film 521 can be used for the insulating film 506.

Specifically, a film including a silicon oxide film, a silicon oxynitride film, a silicon nitride oxide film, a silicon nitride film, an aluminum oxide film, a hafnium oxide film, an yttrium oxide film, a zirconium oxide film, a gallium oxide film, a tantalum oxide film, a magnesium oxide film, a lanthanum oxide film, a cerium oxide film, or a neodymium oxide film can be used as the insulating film 506.

### [Insulating Film 501D]

An insulating film 501D includes a region positioned between the insulating film 501C and the insulating film 516.

For example, a material that can be used for the insulating film 506 can be used for the insulating film 501D.

### [Insulating Film 501C]

For example, a material that can be used for the insulating film 521 can be used for the insulating film 501C. Specifically, a material containing silicon and oxygen can be used for the insulating film 501C. Thus, impurity diffusion into the pixel circuit, the light-emitting element, the photoelectric conversion element, or the like can be inhibited.

### <<Structure Example 3 of Functional Layer 520>>

The functional layer 520 includes a conductive film, a wiring, and a terminal. A conductive material can be used for the wiring, the electrode, the terminal, the conductive film, and the like.

### [Wiring and the Like]

For example, an inorganic conductive material, an organic conductive material, a metal, conductive ceramics, or the like can be used for the wiring and the like.

Specifically, for example, a metal element selected from aluminum, gold, platinum, silver, copper, chromium, tantalum, titanium, molybdenum, tungsten, nickel, iron, cobalt, palladium, and manganese can be used for the wiring and the like. Alternatively, an alloy including any of the above-described metal elements, or the like can be used for the wiring and the like. In particular, an alloy of copper and manganese is suitably used in microfabrication using a wet etching method.

Specifically, the wiring and the like can employ any of the following structures, for example: a two-layer structure in which a titanium film is stacked over an aluminum film; a two-layer structure in which a titanium film is stacked over a titanium nitride film; a two-layer structure in which a tungsten film is stacked over a titanium nitride film; a two-layer structure in which a tungsten film is stacked over a tantalum nitride film or a tungsten nitride film; and a three-layer structure in which a titanium film, an aluminum film, and a titanium film are stacked in this order.

Specifically, a conductive oxide such as indium oxide, indium tin oxide, indium zinc oxide, zinc oxide, or zinc oxide to which gallium is added can be used for the wiring and the like.

Specifically, a film containing graphene or graphite can be used for the wiring and the like.

For example, a film containing graphene oxide is formed and is subjected to reduction, so that a film containing graphene can be formed. As a reducing method, a method with application of heat, a method using a reducing agent, or the like can be employed.

For example, a film containing a metal nanowire can be used for the wiring and the like. Specifically, a nanowire containing silver can be used.

Specifically, a conductive polymer can be used for the wiring and the like.

For example, a terminal 519B can be electrically connected to a flexible printed circuit FPC1 with the use of a conductive material (see FIG. 12). Specifically, the terminal 519B can be electrically connected to the flexible printed circuit FPC1 with the use of a conductive material CP.

### <Structure Example 2 of Functional Panel 700>

The functional panel 700 includes a base 510, a base 770, and the sealant 705 (see FIG. 13A). The functional panel 700 also includes a component KB.

### <<Base 510 and Base 770>>

A light-transmitting material can be used for the base 510 or the base 770.

For example, a flexible material can be used for the base 510 or the base 770. Thus, a functional panel having flexibility can be provided.

For example, a material with a thickness greater than or equal to 0.1 mm and less than or equal to 0.7 mm can be used. Specifically, a material polished to a thickness of approximately 0.1 mm can be used. As a result, the base 510 or the base 770 can be lightweight.

A glass substrate having any of the following sizes, for example, can be used as the base 510 or the base 770: the 6th generation (1500 mm×1850 mm), the 7th generation (1870 mm×2200 mm), the 8th generation (2200 mm×2400 mm), the 9th generation (2400 mm×2800 mm), and the 10th generation (2950 mm×3400 mm). Thus, a large-sized display device can be fabricated.

For the base 510 or the base 770, an organic material, an inorganic material, a composite material of an organic material and an inorganic material, or the like can be used.

For example, an inorganic material such as glass, ceramic, or metal can be used. Specifically, non-alkali glass, soda-lime glass, potash glass, crystal glass, aluminosilicate glass, tempered glass, chemically tempered glass, quartz, sapphire, or the like can be used for the base 510 or the base 770. Alternatively, aluminosilicate glass, tempered glass, chemically tempered glass, sapphire, or the like can be favorably used for the base 510 or the base 770 that is on the side closer to a user of the functional panel. This can prevent breakage or damage of the functional panel caused by the use.

Specifically, an inorganic oxide film, an inorganic nitride film, an inorganic oxynitride film, or the like can be used. For example, a silicon oxide film, a silicon nitride film, a silicon oxynitride film, or an aluminum oxide film can be used. Stainless steel, aluminum, or the like can be used for the base 510 or the base 770.

For example, a single crystal semiconductor substrate or a polycrystalline semiconductor substrate made of silicon or silicon carbide, a compound semiconductor substrate made of silicon germanium or the like, or an SOI substrate can be used as the base 510 or the base 770. Thus, a semiconductor element can be formed on the base 510 or the base 770.

For example, an organic material such as a resin, a resin film, or plastic can be used for the base 510 or the base 770. Specifically, a material containing polyester, polyolefin, polyamide (e.g., nylon or aramid), polyimide, polycarbonate, polyurethane, an acrylic resin, an epoxy resin, or a resin having a siloxane bond, such as silicone, can be used for the base 510 or the base 770. For example, a resin film, a resin plate, a layered material, or the like containing any of these materials can be used. As a result, the base 510 or the base 770 can be lightweight. Alternatively, for example, the functional panel can be less likely to suffer from damage by dropping or the like.

Specifically, polyethylene terephthalate (PET), polyethylene naphthalate (PEN), polyethersulfone (PES), a cyclic olefin polymer (COP), a cyclic olefin copolymer (COC), or the like can be used for the base 510 or the base 770.

For example, a composite material formed by attaching a metal plate, a thin glass plate, or a film of an inorganic material or the like and a resin film or the like can be used for the base 510 or the base 770. For example, a composite material formed by dispersing a fibrous or particulate metal, glass, inorganic material, or the like into a resin can be used for the base 510 or the base 770. For example, a composite material formed by dispersing a fibrous or particulate resin, organic material, or the like into an inorganic material can be used for the base 510 or the base 770.

Furthermore, a single-layer material or a material in which a plurality of layers are stacked can be used for the base 510 or the base 770. For example, a material in which insulating films and the like are stacked can be used. Specifically, a material in which one or more films selected from a silicon oxide layer, a silicon nitride layer, a silicon oxynitride layer, and the like are stacked can be used. Thus, diffusion of impurities contained in the base can be prevented, for example. Alternatively, diffusion of impurities contained in glass or a resin can be prevented. Alternatively, diffusion of impurities that pass through a resin can be prevented.

Alternatively, paper, wood, or the like can be used for the base 510 or the base 770.

For example, a material having heat resistance high enough to withstand heat treatment in the manufacturing process can be used for the base 510 or the base 770. Specifically, a material that is resistant to heat applied in the process of forming the transistor, the capacitor, and the like directly on the base can be used for the base 510 or the base 770.

For example, it is possible to employ a method in which an insulating film, a transistor, a capacitor, and the like are formed over a process substrate that is resistant to heat applied in the manufacturing process, and then the formed components are transferred to the base 510 or the base 770, for instance. Thus, the insulating film, the transistor, the capacitor, and the like can be formed over a flexible substrate, for example.

### <<Sealant 705>>

The sealant 705 includes a region positioned between the functional layer 520 and the base 770, and has a function of bonding the functional layer 520 and the base 770 together (see FIG. 13A).

For the sealant 705, an inorganic material, an organic material, a composite material of an inorganic material and an organic material, or the like can be used.

For example, an organic material such as a thermally fusible resin or a curable resin can be used for the sealant 705.

For example, an organic material such as a reactive curable adhesive, a light curable adhesive, a thermosetting adhesive, and/or an anaerobic adhesive can be used for the sealant 705.

Specifically, an adhesive containing an epoxy resin, an acrylic resin, a silicone resin, a phenol resin, a polyimide resin, an imide resin, a polyvinyl chloride (PVC) resin, a polyvinyl butyral (PVB) resin, or an ethylene vinyl acetate (EVA) resin can be used as the sealant 705.

### <<Component KB>>

The component KB includes a region positioned between the functional layer 520 and the base 770. The component KB has a function of providing a certain space between the functional layer 520 and the base 770.

Note that this embodiment can be combined with any of the other embodiments in this specification as appropriate.

### Embodiment 4

In this embodiment, a structure of a functional panel of one embodiment of the present invention will be described with reference to FIGS. 13A and 13B, FIGS. 14A and 14B, and FIGS. 15A and 15B.

### <Structure Example 1 of Functional Panel 700>

The functional panel 700 includes the light-emitting element 550G(i,j) (see FIGS. 13A and 13B).

### <<Structure Example 2 of Light-Emitting Element 550G(i,j)>>

An electrode 551G(i,j), an electrode 552, and a layer 553G(j) containing a light-emitting material can be used in the light-emitting element 550G(i,j). The layer 553G(j) containing a light-emitting material includes a region positioned between the electrode 551G(i,j) and the electrode 552.

### [Structure Example 1 of Layer 553G(j) Containing Light-Emitting Material]

For example, a layered material can be used for the layer 553G(j) containing a light-emitting material.

For example, a material that emits blue light, a material that emits green light, a material that emits red light, a material that emits infrared light, or a material that emits ultraviolet light can be used in the layer 553G(j) containing a light-emitting material.

### [Structure Example 2 of Layer 553G(j) Containing Light-Emitting Material]

For example, a layered material in which materials are stacked to emit while light can be used for the layer 553G(j) containing a light-emitting material.

Specifically, a plurality of materials that emit light with different hues can be used for the layer 553G(j) containing a light-emitting material.

For example, a layered material in which a layer containing a light-emitting material including a fluorescent material that emits blue light and a layer containing materials that are other than a fluorescent material and emit green light and/or red light are stacked can be used for the layer 553G(j) containing a light-emitting material. Alternatively, a layered material in which a layer containing a light-emitting material including a fluorescent material that emits blue light and a layer containing a material that is other than a fluorescent material and emits yellow light are stacked can be used for the layer 553G(j) containing a light-emitting material.

Note that the coloring film, for example, can overlap with the layer 553G(j) containing a light-emitting material. Thus, light of a predetermined hue can be extracted from white light.

### [Structure Example 3 of Layer 553G(j) Containing Light-Emitting Material]

For example, a layered material in which materials are stacked to emit blue light or ultraviolet light can be used for the layer 553G(j) containing a light-emitting material. Moreover, the color conversion layer can overlap with the layer 553G(j) containing a light-emitting material, for example.

### [Structure Example 4 of Layer 553G(j) Containing Light-Emitting Material]

The layer 553G(j) containing a light-emitting material includes a light-emitting unit. The light-emitting unit includes one region where electrons injected from one side are recombined with holes injected from the other side. The light-emitting unit contains a light-emitting material, and the light-emitting material releases energy generated by recombination of electrons and holes as light. Note that a hole-transport layer and an electron-transport layer can be used in the light-emitting unit. The hole-transport layer is positioned closer to the anode than the electron-transport layer is, and has higher hole mobility than the electron-transport layer.

For example, a plurality of light-emitting units and an intermediate layer can be used in the layer 553G(j) containing a light-emitting material. The intermediate layer includes a region positioned between two light-emitting units. The intermediate layer includes a charge-generation region and has functions of supplying holes to the light-emitting unit provided on the cathode side and supplying electrons to the light-emitting unit provided on the anode side. Note that a light-emitting element including a plurality of light-emitting units and an intermediate layer is sometimes referred to as a tandem light-emitting element.

Accordingly, the current efficiency of light emission can be increased. Alternatively, the density of current flowing through the light-emitting element at the same luminance can be reduced. Alternatively, the reliability of the light-emitting element can be increased.

For example, a light-emitting unit including a material that emits light of one hue and a light-emitting unit including a material that emits light of a different hue can be stacked and used in the layer 553G(j) containing a light-emitting material. Alternatively, a light-emitting unit including a material that emits light of one hue and another light-emitting unit including a material that emits light of the same hue can be stacked and used in the layer 553G(j) containing a light-emitting material. Specifically, two light-emitting units each containing a material that emits blue light can be stacked and used.

For example, a high molecular compound (e.g., an oligomer, a dendrimer, or a polymer), a middle molecular compound (a compound with a molecular weight of 400 to 4000 between a low molecular compound and a high molecular compound), or the like can be used for the layer 553G(j) containing a light-emitting material.

### [Electrode 551G(i,j) and Electrode 552]

For example, a material that can be used for the wiring and the like can be used for the electrode 551G(i,j) or the electrode 552. Specifically, a material that transmits visible light can be used for the electrode 551G(i,j) or the electrode 552.

For example, conductive oxide, indium-containing conductive oxide, indium oxide, indium tin oxide, indium zinc oxide, zinc oxide, zinc oxide to which gallium is added, or the like can be used. Alternatively, a metal film that is thin enough to transmit light can be used. Alternatively, a material that transmits visible light can be used.

For example, a metal film that transmits part of light and reflects another part of light can be used as the electrode 551G(i,j) or the electrode 552. The distance between the electrode 551G(i,j) and the electrode 552 is adjusted using the layer 553G(j) containing a light-emitting material, for example.

Accordingly, the light-emitting element 550G(i,j) can be provided with a microcavity structure. Alternatively, light of a predetermined wavelength can be extracted more efficiently than light of the other wavelengths. Alternatively, light with a narrow spectral half-width can be extracted. Alternatively, light of a bright color can be extracted.

For example, a film that reflects light efficiently can be used as the electrode 551G(i,j) or the electrode 552. Specifically, a material containing silver, palladium, and the like or a material containing silver, copper, and the like can be used for the metal film.

The electrode 551G(i,j) is electrically connected to the pixel circuit 530G(i,j) through the opening 591G (see FIG. 14A). The electrode 551G(i,j) overlaps with an opening formed in the insulating film 528, for example, and the outer edge region of the electrode 551G(i,j) is in contact with the insulating film 528.

This structure can prevent a short circuit between the electrode 551G(i,j) and the electrode 552.

### <<Structure Example 2 of Photoelectric Conversion Element PD(i,j)>>

The photoelectric conversion element PD(i,j) includes an electrode 551S(i,j), the electrode 552, and a layer 553S(j) containing a photoelectric conversion material (see FIG. 14A).

For example, a heterojunction photoelectric conversion element or a bulk heterojunction photoelectric conversion element can be used as the photoelectric conversion element PD(i,j).

### [Structure Example 1 of Layer 553S(j) Containing Photoelectric Conversion Material]

For example, a stacked-layer film in which a p-type semiconductor film and an n-type semiconductor film are stacked in contact with each other can be used as the layer 553S(j) containing a photoelectric conversion material. Note that the photoelectric conversion element PD(i,j) in which a stacked-layer film with such a structure is used as the layer 553S(j) containing a photoelectric conversion material can be referred to as a PN photodiode.

For example, a stacked-layer film in which a p-type semiconductor film, an i-type semiconductor film, and an n-type semiconductor film are stacked so that the i-type semiconductor film is positioned between the p-type semiconductor film and the n-type semiconductor film can be used as the layer 553S(j) containing a photoelectric conversion material. Note that the photoelectric conversion element PD(i,j) in which a stacked-layer film with such a structure is used as the layer 553S(j) containing a photoelectric conversion material can be referred to as a PIN photodiode.

For example, a stacked-layer film in which a pt-type semiconductor film, a p⁻-type semiconductor film, a p-type semiconductor film, and an n-type semiconductor film are stacked so that the p⁻-type semiconductor film is positioned between the pt-type semiconductor film and the n-type semiconductor film and the p-type semiconductor film is positioned between the p⁻-type semiconductor film and the n-type semiconductor film can be used as the layer 553S(j) containing a photoelectric conversion material. Note that the photoelectric conversion element PD(i,j) in which a stacked-layer film with such a structure is used as the layer 553S(j) containing a photoelectric conversion material can be referred to as an avalanche photodiode.

### [Structure Example 2 of Layer 553S(j) Containing Photoelectric Conversion Material]

For example, a semiconductor containing a Group 14 element can be used for the layer 553S(j) containing a photoelectric conversion material. Specifically, a semiconductor containing silicon can be used for the layer 553S(j) containing a photoelectric conversion material. For example, hydrogenated amorphous silicon, microcrystalline silicon, polysilicon, or single crystal silicon can be used for the layer 553S(j) containing a photoelectric conversion material.

For example, an organic semiconductor can be used for the layer 553S(j) containing a photoelectric conversion material. Specifically, part of the layer used as the layer 553G(j) containing a light-emitting material can be used as part of the layer 553S(j) containing a photoelectric conversion material.

Specifically, a hole-transport layer that is used as the layer 553G(j) containing a light-emitting material can be used as the layer 553S(j) containing a photoelectric conversion material. Alternatively, an electron-transport layer that is used as the layer 553G(j) containing a light-emitting material can be used as the layer 553S(j) containing a photoelectric conversion material. Alternatively, the hole-transport layer and the electron-transport layer can be used as the layer 553S(j) containing a photoelectric conversion material. Thus, in a step of forming the hole-transport layer that is used as the layer 553G(j) containing a light-emitting material, the hole-transport layer that is used as the layer 553S(j) containing a photoelectric conversion material can be formed. Alternatively, in a step of forming the electron-transport layer that is used as the layer 553G(j) containing a light-emitting material, the electron-transport layer that is used as the layer 553S(j) containing a photoelectric conversion material can be formed. Alternatively, the manufacturing process can be simplified.

For example, an electron-accepting organic semiconductor material such as fullerene (e.g., C60 or C70) or its derivative can be used for the n-type semiconductor film.

For example, an electron-donating organic semiconductor material such as copper(II) phthalocyanine (CuPc) or tetraphenyldibenzoperiflanthene (DBP) can be used for the p-type semiconductor film.

For example, a film obtained by co-evaporation of an electron-accepting semiconductor material and an electron-donating semiconductor material can be used as the i-type semiconductor film.

### <Structure Example 2 of Functional Panel 700>

The functional panel 700 includes the insulating film 528 and an insulating film 573 (see FIG. 13A).

### <<Insulating Film 528>>

The insulating film 528 includes a region positioned between the functional layer 520 and the base 770 and has an opening in a region overlapping with the light-emitting element 550G(i,j) (see FIG. 13A).

For example, a material that can be used for the insulating film 521 can be used for the insulating film 528. Specifically, a silicon oxide film, a film containing an acrylic resin, a film containing polyimide, or the like can be used as the insulating film 528.

### <<Insulating Film 573>>

The insulating film 573 includes a region where the light-emitting element 550G(i,j) is positioned between the functional layer 520 and the insulating film 573 (see FIG. 13A).

For example, a single film or a stacked-layer film in which a plurality of films are stacked can be used as the insulating film 573. Specifically, a stacked-layer film in which an insulating film 573A capable of being formed by a method that hardly damages the light-emitting element 550G(i,j) and a dense insulating film 573B with a few defects are stacked can be used as the insulating film 573.

Thus, diffusion of impurities into the light-emitting element 550G(i,j) can be inhibited. Alternatively, the reliability of the light-emitting element 550G(i,j) can be increased.

<Structure Example 3 of functional panel 700>

The functional panel 700 includes a functional layer 720 (see FIG. 13A).

<<Functional layer 720>>

The functional layer 720 includes the light-blocking film BM, the coloring film CF(G), and an insulating film 771. In addition, a color conversion layer can be used.

<<Light-blocking film BM>>

The light-blocking film BM has an opening in a region overlapping with the pixel 702G(i,j). Moreover, the light-blocking film BM has an opening in a region overlapping with the pixel 702S(i,j).

For example, a material of a dark color can be used for the light-blocking film BM. Thus, the display contrast can be increased.

<<Coloring film CF(G)>>

The coloring film CF(G) includes a region positioned between the base 770 and the light-emitting element 550G(i,j). For example, a material that selectively transmits light of a predetermined color can be used for the coloring film CF(G). Specifically, a material that transmits red light, green light, or blue light can be used for the coloring film CF(G).

<<<Structure example of insulating film 771>>

The insulating film 771 includes a region positioned between the base 770 and the light-emitting element 550G(i,j).

The insulating film 771 includes a region where the light-blocking film BM, the coloring film CF(G), or the color conversion layer is positioned between the base 770 and the insulating film 771. Thus, unevenness due to the thickness of the light-blocking film BM, the coloring film CF(G), or the color conversion layer can be reduced or eliminated.

### <<Color Conversion Layer>>

The color conversion layer includes a region positioned between the base 770 and the light-emitting element 550G(i,j).

For example, a material that emits light with a wavelength longer than that of incident light can be used for the color conversion layer. For example, a material that absorbs blue light or ultraviolet light, converts it into green light, and emits green light; a material that absorbs blue light or ultraviolet light, converts it into red light, and emits red light; or a material that absorbs ultraviolet light, converts it into blue light, and emits blue light can be used for the color conversion layer. Specifically, quantum dots with a diameter of several nanometers can be used for the color conversion layer. Thus, light with a narrow spectral half-width can be released. Alternatively, light with high saturation can be released.

<Structure Example 4 of functional panel 700>

The functional panel 700 includes a light-blocking film KBM (see FIG. 13A).

### <<Light-Blocking Film KBM>>

The light-blocking film KBM has an opening in a region overlapping with the pixel 702S(i,j). Moreover, the light-blocking film KBM includes a region positioned between the functional layer 520 and the base 770, and has a function of providing a certain space between the functional layer 520 and the base 770. For example, a material of a dark color can be used for the light-blocking film KBM. Thus, stray light that would enter the pixel 702S(i,j) can be reduced.

### <Structure Example 5 of Functional Panel 700>

The functional panel 700 includes a functional film 770P (see FIG. 13A).

### <<Functional Film 770P>>

The functional film 770P includes a region overlapping with the light-emitting element 550G(i,j).

For example, an anti-reflection film, a polarizing film, a retardation film, a light diffusion film, a condensing film, or the like can be used as the functional film 770P.

For example, an anti-reflection film with a thickness of 1 μm or less can be used as the functional film 770P. Specifically, a stacked-layer film in which three or more, preferably five or more, further preferably 15 or more dielectrics are stacked can be used as the functional film 770P. This allows the reflectivity to be as low as 0.5% or less, preferably 0.08% or less.

For example, a circularly polarizing film can be used as the functional film 770P.

Furthermore, an antistatic film preventing the attachment of a foreign substance, a water repellent film preventing stains, an oil repellent film preventing stains, an anti-reflection film, an anti-glare (non-glare) film, a hard coat film inhibiting a scratch in use, a self-healing film that self-heals from scratches, or the like can be used as the functional film 770P.

Note that this embodiment can be combined with any of the other embodiments in this specification as appropriate.

### Embodiment 5

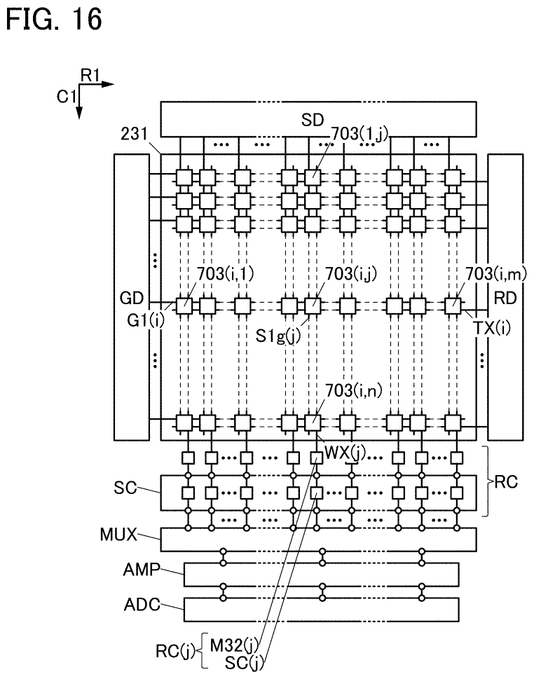

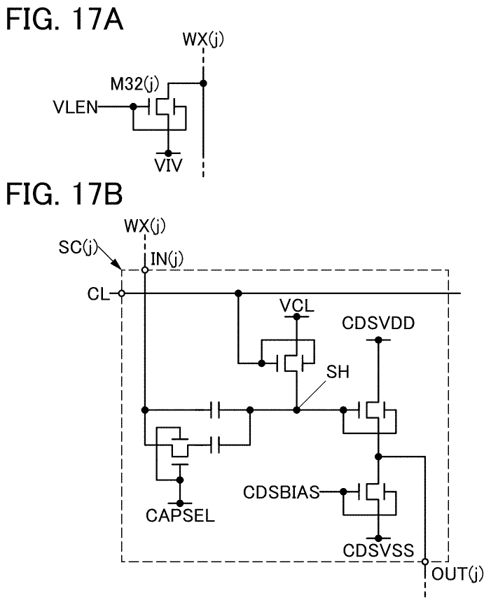

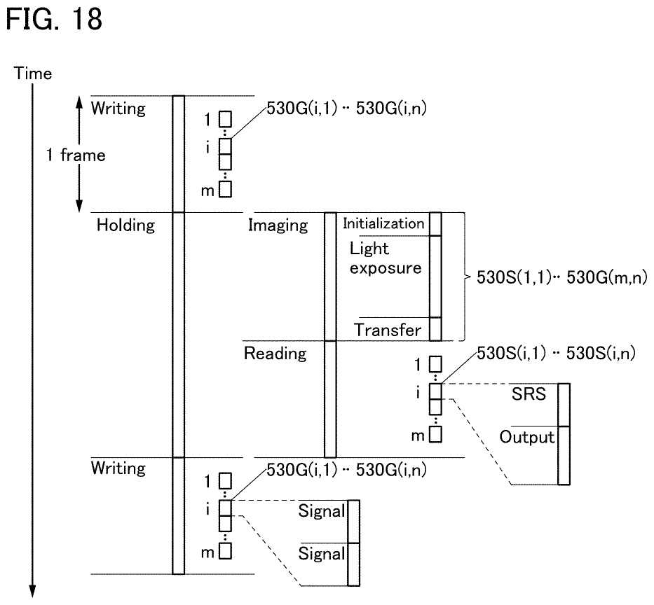

In this embodiment, a structure of a functional panel of one embodiment of the present invention will be described with reference to FIG. 16, FIGS. 17A and 17B, and FIG. 18.

FIG. 16 illustrates a structure of a functional panel of one embodiment of the present invention.

FIGS. 17A and 17B are circuit diagrams illustrating a structure of a functional panel of one embodiment of the present invention. FIG. 17A is a circuit diagram illustrating part of an amplifier circuit that can be used in a functional panel of one embodiment of the present invention. FIG. 17B is a circuit diagram illustrating part of a sampling circuit that can be used in a functional panel of one embodiment of the present invention.

FIG. 18 illustrates operation of a functional panel of one embodiment of the present invention.

<Structure Example 1 of functional panel 700>

The functional panel 700 of one embodiment of the present invention includes a region 231 (see FIG. 16).

### <<Structure Example 1 of Region 231>>

The region 231 includes a group of pixels 703(i,1) to 703(i,n) and another group of pixels 703(i,j) to 703(m,j). The region 231 also includes the conductive film G1(i), the conductive film TX(i), the conductive film S1g(j), and the conductive film WX(j).

The group of pixels 703(i,1) to 703(i,n) are arranged in the row direction (the direction indicated by the arrow R1 in FIG. 16) and include the pixel 703(i,j).

The group of pixels 703(i,1) to 703(i,n) are electrically connected to the conductive film G1(i) and the conductive film TX(i).

The another group of pixels 703(1,j) to 703(m,j) are arranged in the column direction intersecting the row direction (the direction indicated by the arrow C1 in FIG. 16) and include the pixel 703(i,j).

The another group of pixels 703(1,j) to 703(m,j) are electrically connected to the conductive film S1g(j) and the conductive film WX(j).

With the above structure, imaging data can be obtained from a plurality of pixels. Alternatively, image data can be supplied to a plurality of pixels. Thus, a novel functional panel that is highly convenient, useful, or reliable can be provided.

### <<Structure Example 2 of Region 231>>

The region 231 includes 600 or more pixels per inch. Note that the pixels include the pixel 703(i,j).

### <<Structure Example 3 of Region 231>>

The region 231 includes a plurality of pixels in a matrix. For example, the region 231 includes 7600 or more pixels in the row direction and 4300 or more pixels in the column direction. Specifically, 7680 pixels are provided in the row direction, and 4320 pixels are provided in the column direction.

Such a structure makes it possible to display a high-definition image. Thus, a novel functional panel that is highly convenient, useful, or reliable can be provided.

### <<Structure Example 4 of Region 231>>

The diagonal of the region 231 is greater than or equal to 40 inches, preferably greater than or equal to 60 inches, more preferably greater than or equal to 80 inches. The diagonal of the region 231 is preferably less than or equal to 150 inches, in which case the weight of the panel can be reduced.

Thus, a realistic image can be displayed. Thus, a novel functional panel that is highly convenient, useful, or reliable can be provided.

Although not illustrated, the region 231 includes a conductive film VCOM2 and the conductive film ANO.

### <Structure Example 2 of Functional Panel 700>

The functional panel described in this embodiment includes the driver circuit GD (see FIG. 16).

### <<Structure Example 1 of Driver Circuit GD>>

The driver circuit GD supplies a first selection signal.

### <<Structure Example 1 of Pixel Circuit 530G(i,j)>>

The pixel circuit 530G(i,j) is supplied with the first selection signal and obtains an image signal in accordance with the first selection signal. For example, the first selection signal can be supplied using the conductive film G1(i) (see FIG. 9B). The image signal can be supplied using the conductive film S1g(j). Note that the operation of supplying the first selection signal and making the pixel circuit 530G(i,j) obtain an image signal can be referred to as “writing” (see FIG. 18).

The light-emitting element 550G(i,j) emits light on the basis of the image signal (see FIG. 9B).

The light-emitting element 550G(i,j) includes the electrode 551G(i,j) electrically connected to the pixel circuit 530G(i,j), and the electrode 552 electrically connected to the conductive film VCOM2 (see FIG. 10 and FIG. 13A).

### <Structure Example 3 of Functional Panel 700>

A functional panel of one embodiment of the present invention includes a read circuit RC(j), a conductive film VLEN, a conductive film VIV, and a conductive film CL (see FIG. 16, FIG. 11, and FIGS. 17A and 17B).

### <<Structure Example of Read Circuit RC(j)>>

The read circuit RC(j) includes an amplifier circuit and a sampling circuit SC(j) (see FIG. 16).

### <<Structure Example of Amplifier Circuit>>

The amplifier circuit includes a transistor M32(j) (see FIG. 17A).

The transistor M32(j) includes a gate electrode electrically connected to the conductive film VLEN, a first electrode electrically connected to the conductive film WX(j), and a second electrode electrically connected to the conductive film VIV.

Note that the conductive film WX(j) connects the transistor M31(i) and the transistor M32(j) when the switch SW33 is on (see FIG. 11 and FIG. 17A). Thus, a source follower circuit can be configured with the transistor M31(i) and the transistor M32(j). Alternatively, the potential of the conductive film WX(j) can be changed on the basis of the potential of the node FD.

<<Structure Example of sampling circuit SC(j)>>

The sampling circuit SC(j) includes a first terminal IN(j), a second terminal, and a third terminal OUT(j) (see FIG. 17B).

The first terminal IN(j) is electrically connected to the conductive film WX(j). The second terminal is electrically connected to the conductive film CL. The third terminal OUT(j) has a function of supplying a signal that changes on the basis of the potential of the first terminal IN(j).

Accordingly, an imaging signal can be obtained from the pixel circuit 530S(i,j). Alternatively, a correlated double sampling method can be employed, for example. Alternatively, the sampling circuit SC(j) can be provided for each conductive film WX(j). Alternatively, a differential signal of the pixel circuit 530S(i,j) can be obtained by the corresponding conductive film WX(j). Alternatively, the operating frequency of the sampling circuit SC(j) can be low. Alternatively, noise can be reduced. As a result, a novel functional panel that is highly convenient, useful, or reliable can be provided. Thus, a novel functional panel that is highly convenient, useful, or reliable is provided.

### <Structure Example 4 of Functional Panel 700>

The functional panel 700 includes the driver circuit RD (see FIG. 16).

<<Structure Example 1 of driver circuit RD>>

The driver circuit RD supplies a second selection signal and a third selection signal.

### <<Structure Example 1 of Pixel Circuit 530S(i,j)>>

The pixel circuit 530S(i,j) is supplied with the second selection signal and the third selection signal in a period during which the first selection signal is not supplied (see FIG. 18). In addition, the pixel circuit 530S(i,j) obtains an imaging signal on the basis of the second selection signal, and supplies the imaging signal on the basis of the third selection signal. For example, the second selection signal can be supplied using the conductive film TX(i), and the third selection signal can be supplied using the conductive film SE(i) (see FIG. 11).

Note that the operation of supplying the second selection signal and making the pixel circuit 530S(i,j) obtain an imaging signal can be referred to as “imaging” (see FIG. 18). The operation of reading an imaging signal from the pixel circuit 530S(i,j) can be referred to as “reading”. The operation of supplying a predetermined voltage to the photoelectric conversion element PD(i,j) can be referred to as “initialization”, the operation of exposing the initialized photoelectric conversion element PD(i,j) to light in a predetermined period as “light exposure”, and the operation of reflecting a voltage that has been changed along with the light exposure on the pixel circuit 530S(i,j) as “transfer”. Moreover, in FIG. 18, “SRS” corresponds to the operation of supplying a reference signal used in a correlated double sampling method, and “output” corresponds to the operation of supplying an imaging signal.

For example, image data for one frame can be written in 16.7 ms. Specifically, the operation can be performed at a frame rate of 60 Hz. Note that an image signal can be written to the pixel circuit 530G(i,j) in 15.2 μs.

For example, image data of one frame can be held in a period corresponding to 16 frames. Alternatively, imaging data of one frame can be captured and read out in a period corresponding to 16 frames.

Specifically, it is possible to perform the initialization in 15 μs, the light exposure in a period from 1 ms to 5 ms, and the transfer in 150 μs. Moreover, the reading can be performed in 250 ms.

The photoelectric conversion element PD(i,j) includes the electrode 551S(i,j) electrically connected to the pixel circuit 530S(i,j), and the electrode 552 electrically connected to a conductive film VPD (see FIG. 11 and FIG. 14A). The electrode 552 used in the light-emitting element 550G(i,j) can be used in the photoelectric conversion element PD(i,j). In this manner, the structure and the manufacturing process of the functional panel can be simplified.

Accordingly, imaging can be performed in a period during which the first selection signal is not supplied. Alternatively, noise in imaging can be suppressed. Alternatively, an imaging signal can be read out in a period during which the first selection signal is not supplied. Alternatively, noise in reading can be suppressed. Thus, a novel functional panel that is highly convenient, useful, or reliable can be provided.

<<Structure Example 3 of Pixel 703(i,j)>>

The pixel 703(i,j) is supplied with the second selection signal in a period during which the pixel 703(i,j) holds one image signal. For example, in a period during which the pixel circuit 530G(i,j) holds one image signal, the pixel 703(i,j) can emit light with the use of the light-emitting element 550G(i,j) on the basis of the image signal (see FIG. 18). Alternatively, the pixel circuit 530S(i,j) is supplied with the second selection signal after the pixel circuit 530G(i,j) obtains one image signal on the basis of the first selection signal until the pixel circuit 530G(i,j) is supplied with the first selection signal again.

Accordingly, the intensity of light emitted from the light-emitting element 550G(i,j) can be controlled using the image signal. Alternatively, light having a controlled intensity can be emitted to a subject. Alternatively, an image of the subject can be taken using the photoelectric conversion element PD(i,j). Alternatively, an image of the subject can be taken using the photoelectric conversion element PD(i,j) while the intensity of emitted light is controlled. Alternatively, the influence of a change from one to another of image signals held in the pixel circuit 530G(i,j) on an imaging signal can be eliminated. Thus, a novel functional panel that is highly convenient, useful, or reliable can be provided.

### <Structure Example 5 of Functional Panel 700>

The functional panel 700 of one embodiment of the present invention includes a multiplexer MUX, an amplifier circuit AMP, and an analog-to-digital converter circuit ADC (see FIG. 16).

### <<Structure Example of Multiplexer MUX>>

The multiplexer MUX has a function of obtaining an imaging signal from one selected from a plurality of sampling circuits SC and supplying the imaging signal to the amplifier circuit AMP, for example.

For example, the multiplexer MUX is electrically connected to the third terminal OUT(j) of the sampling circuit SC(j) (see FIG. 17B). Specifically, the multiplexer MUX is electrically connected to sampling circuits SC(1) to SC(9), and can obtain an imaging signal from a given sampling circuit and supply the image signal to the amplifier circuit AMP.

Thus, imaging data can be obtained by selecting a given pixel from a plurality of pixels arranged in the row direction. Alternatively, the number of imaging signals acquired at the same time can be limited to a predetermined number. Alternatively, it is possible to use the analog-to-digital converter circuit ADC in which the number of input channels is smaller than the number of pixels arranged in the row direction. Thus, a novel functional panel that is highly convenient, useful, or reliable can be provided.

### <<Structure Example of Amplifier Circuit AMP>>

The amplifier circuit AMP can amplify an imaging signal and supply the amplified signal to the analog-to-digital converter circuit ADC.

Note that the functional layer 520 includes the multiplexer MUX and the amplifier circuit AMP.

Accordingly, for example, in a step of forming the semiconductor film used in the pixel circuit 530G(i,j), semiconductor films used in the multiplexer MUX and the amplifier circuit AMP can be formed. Alternatively, the manufacturing process of the functional panel can be simplified. As a result, a novel functional panel that is highly convenient, useful, or reliable can be provided.

### <<Structure Example of Analog/Digital Converter Circuit ADC>>

An analog/digital converter circuit ADC has a function of converting an analog imaging signal to a digital signal. This can suppress deterioration of an imaging signal due to transmission.

Note that this embodiment can be combined with any of the other embodiments in this specification as appropriate.

### Embodiment 6

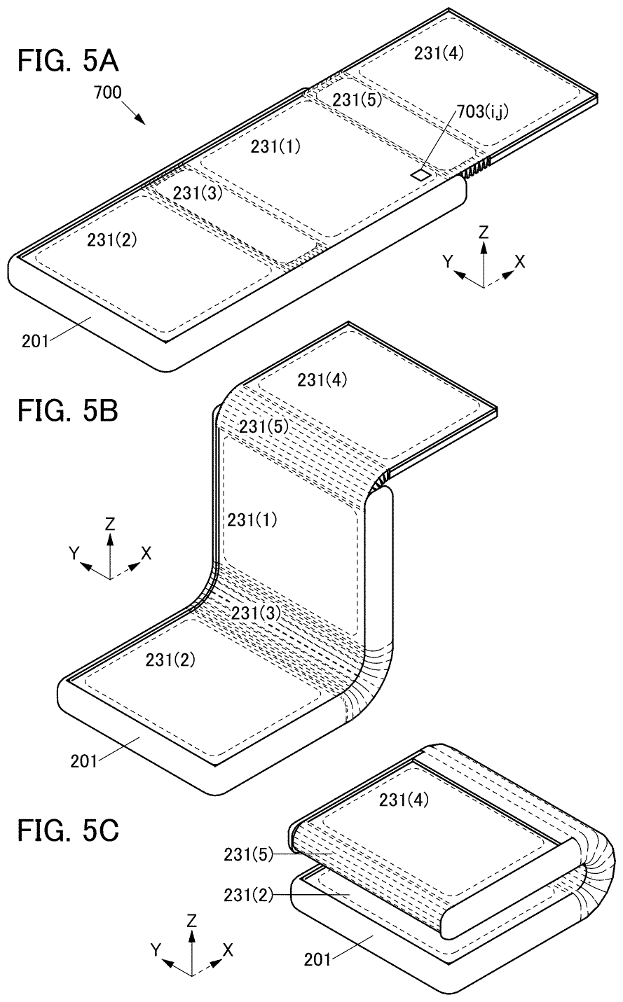

In this embodiment, structures of a semiconductor device of one embodiment of the present invention will be described with reference to FIGS. 5A to 5C, FIGS. 6A to 6C, and FIGS. 7A and 7B.

FIGS. 5A to 5C illustrate a structure of a semiconductor device of one embodiment of the present invention. FIG. 5A is a perspective view of the semiconductor device of one embodiment of the present invention, and FIGS. 5B and 5C each illustrate a state where part of the semiconductor device illustrated in FIG. 5A is bent.

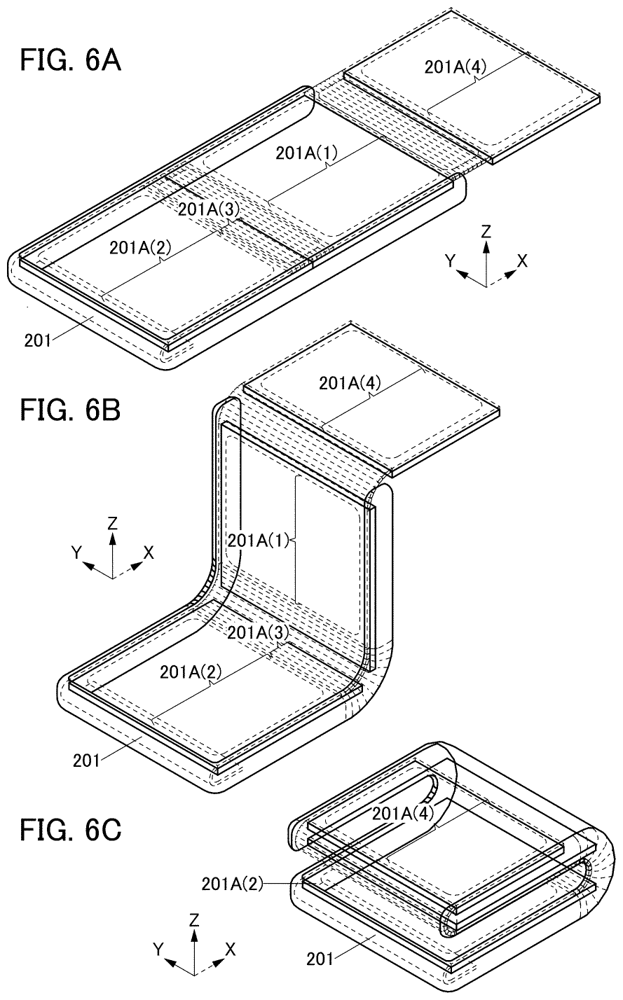

FIGS. 6A to 6C illustrate a structure of a housing that can be used in the semiconductor device of one embodiment of the present invention. FIG. 6A is a perspective view of the housing of the semiconductor device of one embodiment of the present invention, and FIGS. 6B and 6C each illustrate a state where part of the housing of the semiconductor device illustrated in FIG. 6A is bent.

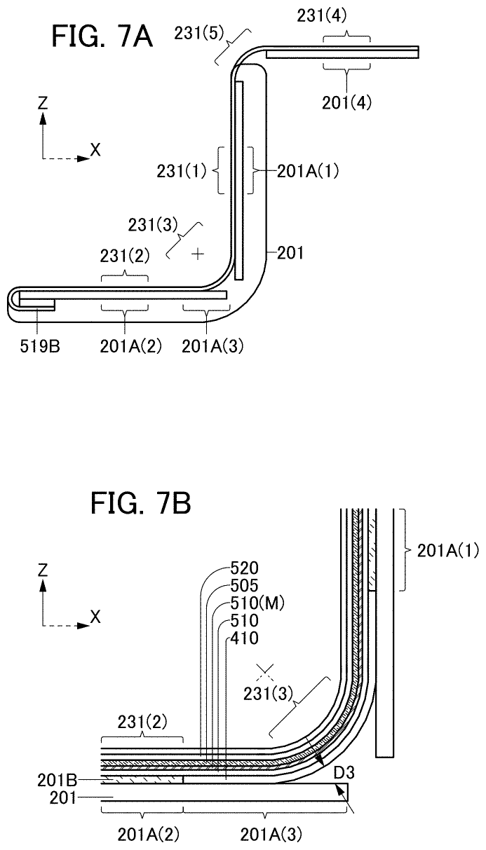

FIGS. 7A and 7B illustrate a structure of the semiconductor device of one embodiment of the present invention. FIG. 7A is a cross-sectional view illustrating the semiconductor device of one embodiment of the present invention illustrated in FIG. 5B, and FIG. 7B illustrates part of FIG. 7A.

### <Structure Example 1 of Semiconductor Device>

The semiconductor device described in this embodiment includes a functional panel and a housing 201 (see FIGS. 5A to 5C). For example, any of the functional panels described in Embodiments 1 to 5 can be used in the semiconductor device.

### <<Structure Example 1 of Housing 201>>

The housing 201 includes a plane 201A(1), a plane 201A(2), and a plane 201A(3) (see FIGS. 6A and 6B).

The plane 201A(3) is positioned between the plane 201A(1) and the plane 201A(2) (see FIG. 6B and FIG. 7A).

The plane 201A(1) and the region 231(1) overlap with each other, the plane 201A(2) and the region 231(2) overlap with each other, and there is a distance D3 between the plane 201A(3) and the region 231(3) (see FIG. 7B). The distance D3 is changed by bending.

Thus, for example, even when the distance D3 between the housing 201 and the circuit 530 is changed by bending of the third region 231(3), the circuit 530 can operate stably. Furthermore, the first conductive film 510M can be protected from an external force or the like with the use of the first base 510. Thus, a novel semiconductor device that is highly convenient, useful, or reliable can be provided.

Note that the region 231(3) is attachable to and detachable from the plane 201A(3), and the region 231(2) is fixed to the plane 201A(2). For example, a bonding layer 201B can be used to fix the region 231(2) to the plane 201A(2). The thickness of the bonding layer 201B is the same as the thickness of the base 410. This can make a step between the region 231(2) and the region 231(3) small. Furthermore, a user is less likely to notice the step when, for example, the user touches a boundary between the region 231(2) and the region 231(3) with a finger.

Note that this embodiment can be combined with any of the other embodiments in this specification as appropriate.

### Embodiment 7

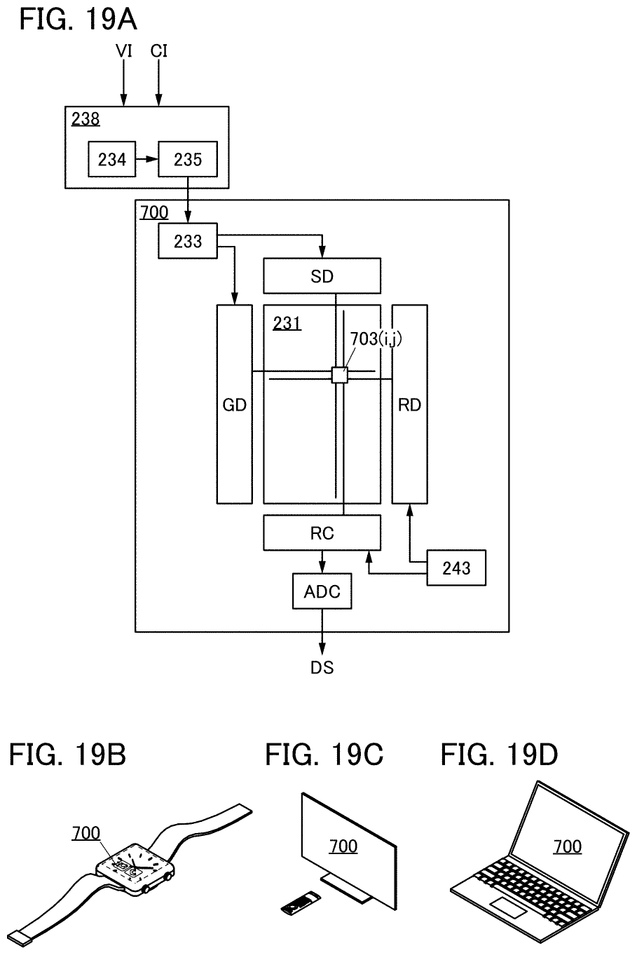

In this embodiment, a structure of a display device of one embodiment of the present invention will be described with reference to FIGS. 19A to 19D.

FIGS. 19A to 19D each illustrate a structure of a display device of one embodiment of the present invention. FIG. 19A is a block diagram of a display device of one embodiment of the present invention. FIGS. 19B to 19D are projection views each illustrating the appearance of a display device of one embodiment of the present invention.

### <Structure Example of Display Device>

The display device described in this embodiment includes the functional panel 700 and a control portion 238 (see FIG. 19A).

### <<Structure Example 1 of Control Portion 238>>

The control portion 238 is supplied with image data VI and control data CI. For example, a clock signal, a timing signal, or the like can be used as the control data CI.

The control portion 238 generates data V11 on the basis of the image data VI and generates a control signal on the basis of the control data CI. Moreover, the control portion 238 supplies the data V11 and the control signal.

For example, the data V11 includes gray levels of 8 bits or more, preferably 12 bits or more. A clock signal, a start pulse, or the like of a shift register used in a driver circuit, for example, can be used as the control signal.

### <<Structure Example 2 of Control Portion 238>>

For example, a decompression circuit 234 and an image processing circuit 235 can be used in the control portion 238.

### <<Decompression Circuit 234>>

The decompression circuit 234 has a function of decompressing the image data VI that is supplied in a compressed state. The decompression circuit 234 includes a memory unit. The memory unit has a function of storing decompressed image data, for example.

### <<Image Processing Circuit 235>>

The image processing circuit 235 includes a memory region, for example. The memory region has a function of storing data contained in the image data VI, for example.

The image processing circuit 235 has a function of generating data by correcting the image data VI on the basis of a predetermined characteristics curve and a function of supplying the data, for example.

### <<Structure Example 1 of Functional Panel>>

The functional panel 700 is supplied with the data and the control signal. For example, the functional panel 700 described in any of Embodiments 1 to 5 can be used.

<<Structure Example 5 of Pixel 703(i,j)>>

The pixel 70301) performs display on the basis of the data.

Thus, the image data can be displayed using a display element. Consequently, a novel display device that is highly convenient, useful, or reliable can be provided. For example, an information terminal (see FIG. 19B), a video display system (see FIG. 19C), and a computer (see FIG. 19D) can be provided.

### <<Structure Example 2 of Functional Panel>>

For example, the functional panel 700 includes driver circuits and control circuits (see FIG. 19A).

### <<Driver Circuit>>

The driver circuit operates on the basis of the control signal. The use of the control signal enables a plurality of driver circuits to operate in synchronization with each other.

For example, the driver circuit GD can be used in the functional panel 700. The driver circuit GD is supplied with the control signal and has a function of supplying a first selection signal.

For example, a driver circuit SD can be used in the functional panel 700. The driver circuit SD is supplied with the control signal and the data, and can supply an image signal.

For example, the driver circuit RD can be used in the functional panel 700. The driver circuit RD is supplied with the control signal and can supply a second selection signal.

For example, the read circuit RC can be used in the functional panel 700. The read circuit RC is supplied with the control signal, and can read out an imaging signal by a correlated double sampling method, for example.

### <<Control Circuit>>

A control circuit has a function of generating and supplying the control signal. For example, a clock signal, a timing signal, or the like can be used as the control signal.

Specifically, a control circuit formed over a rigid substrate can be used in the functional panel. Alternatively, a control circuit formed over a rigid substrate can be electrically connected to the control portion 238 with the use of a flexible printed circuit.

For example, a timing controller 233 can be used for the control circuit. With the use of a control circuit 243, operation of the driver circuit RD can be synchronized with operation of the reading circuit RC.

Note that this embodiment can be combined with any of the other embodiments in this specification as appropriate.

### Embodiment 8

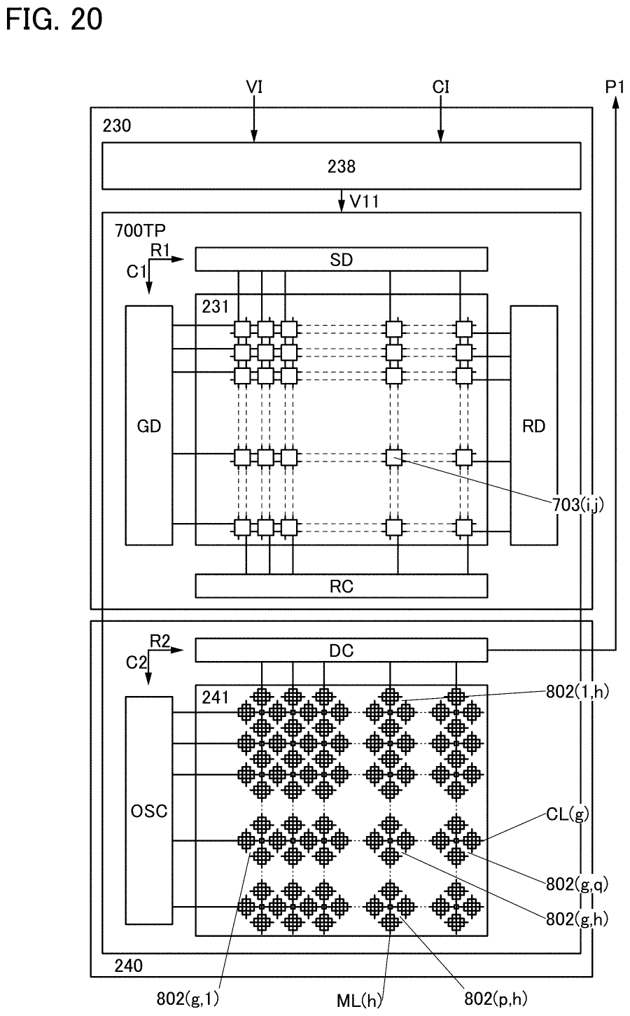

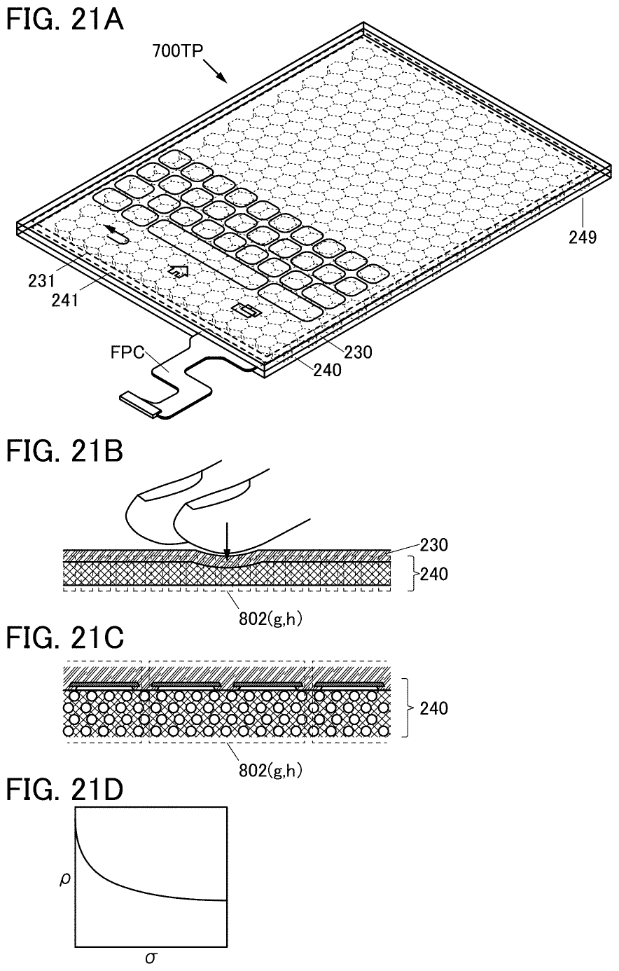

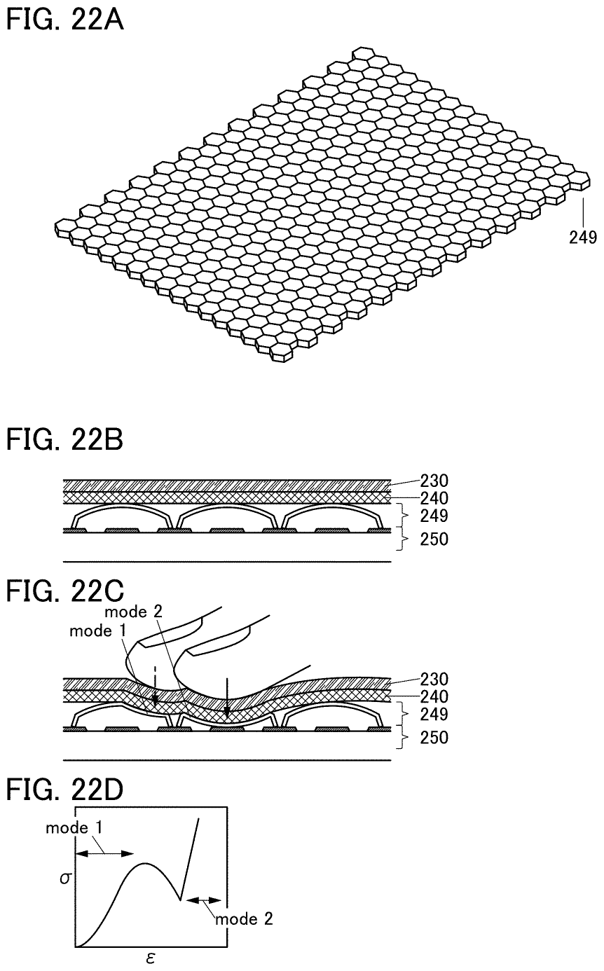

In this embodiment, a structure of an input/output device of one embodiment of the present invention will be described with reference to FIG. 20, FIGS. 21A to 21D, and FIGS. 22A to 22D.

FIG. 20 is a block diagram illustrating a structure of an input/output device of one embodiment of the present invention.

FIGS. 21A to 21D illustrate the structure of the input/output device of one embodiment of the present invention. FIG. 21A is a perspective view of the input/output device of one embodiment of the present invention. FIGS. 21B and 21C are cross-sectional views illustrating part of FIG. 21A. FIG. 21D shows an electric resistance-stress curve which schematically illustrates characteristics of a sensor.

FIGS. 22A to 22D illustrate the structure of the input/output device of one embodiment of the present invention. FIG. 22A is a perspective view of the input/output device of one embodiment of the present invention. FIGS. 22B and 22C are cross-sectional views illustrating part of FIG. 21A. FIG. 22D shows stress-distortion curve which schematically illustrates characteristics of a component in which snap-through buckling occurs.

### <Structure Example 1 of Input/Output Device>

The input/output device described in this embodiment includes an input portion 240 and a display portion 230 (see FIG. 20).

### <<Display Portion 230>>

The display portion 230 includes a functional panel. For example, the functional panel 700 described in any of Embodiments 1 to 5 can be used as the display portion 230. Note that a panel including the input portion 240 and the display portion 230 can be referred to as an input/output panel 700TP.

### <<Structure Example 1 of Input Portion 240>>

The input portion 240 includes a sensing region 241. The input portion 240 has a function of sensing an object approaching the sensing region 241.

The sensing region 241 includes a region overlapping with the pixel 702G(i,j).

Accordingly, an object that approaches the region overlapping with the display portion can be sensed while image data is displayed using the display portion. Alternatively, a finger or the like that approaches the display portion can be used as a pointer to input positional data. Alternatively, positional data can be associated with image data displayed on the display portion. Consequently, a novel input/output device that is highly convenient, useful, or reliable can be provided.

### <<Structure Example 1 of Sensing Region 241>>

The sensing region 241 can include one or more sensors, for example (see FIG. 20).

The sensing region 241 includes a group of sensors 802(g,1) to 802(g,q) and another group of sensors 802(1,h) to 802(p,h). Note that g is an integer greater than or equal to 1 and less than or equal to p, h is an integer greater than or equal to 1 and less than or equal to q, and each of p and q is an integer greater than or equal to 1.

The group of the sensors 802(g,1) to 802(g,q) include the sensor 802(g,h) and are arranged in the row direction (the direction indicated by the arrow R2 in FIG. 20). Note that the direction indicated by the arrow R2 may be the same as or different from the direction indicated by the arrow R1.

The another group of sensors 802(1,h) to 802(p,h) include the sensor 802(g,h) and are arranged in the column direction intersecting the row direction (the direction indicated by the arrow C2 in FIG. 20).

### <<Sensor>>

The sensor has a function of sensing an approaching pointer. For example, a finger or a stylus pen can be used as the pointer. For example, a piece of metal or a coil can be used as the stylus pen.

Specifically, a capacitive proximity sensor, an electromagnetic inductive proximity sensor, an optical proximity sensor, a resistive proximity sensor, or the like can be used as the sensor.

Alternatively, a plurality of kinds of sensors can be used in combination. For example, a sensor that senses a finger and a sensor that senses a stylus pen can be used in combination.

Accordingly, the kind of a pointer can be identified. Alternatively, a different instruction can be associated with sensing data on the basis of the kind of the identified pointer. Specifically, when a finger is identified as being used as the pointer, sensing data can be associated with a gesture. Meanwhile, when a stylus pen is identified as being used as the pointer, sensing data can be associated with drawing processing.

Specifically, a finger can be sensed using a capacitive, pressure-sensitive, or optical proximity sensor. Alternatively, a stylus pen can be sensed using an electromagnetic inductive or optical proximity sensor.

### <<Structure Example 2 of Input Portion 240>>

The input portion 240 can include an oscillator circuit OSC and a sensor circuit DC (see FIG. 20).

The oscillator circuit OSC supplies a search signal to the sensor 802(g,h). For example, a rectangular wave, a sawtooth wave, a triangular wave, or a sine wave can be used as the search signal.

The sensor 802(g,h) generates and supplies a sensing signal that changes in accordance with the search signal and the distance to a pointer approaching the sensor 802(g,h).

The sensor circuit DC supplies input data in accordance with the sensing signal.

Accordingly, the distance from an approaching pointer to the sensing region 241 can be sensed. Alternatively, the position in the sensing region 241 where the pointer comes the closest can be sensed.

### <<Structure Example 1 of Sensor>>

The region 231 is provided closer to the side where the pointer approaches than the sensing region 241 is, and has flexibility (see FIGS. 21A and 21B). For example, an image indicating a keyboard can be displayed on the region 231 (see FIG. 21A).

### <<Structure Example 2 of Sensor>>

The sensor 802(g,h) has a function of sensing the pushing depth and senses a pointer through the region 231 (see FIG. 21B).

For example, the sensor 802(g,h) senses the pushing depth toward the sensor 802(g,h) with the pointer. Specifically, the sensor 802(g,h) senses the pushing depth from a plane including the region 231 to a plane including the sensing region 241 with a finger or a stylus (see FIG. 21C).

For example, a pressure sensor can be used as the sensor 802(g,h). Specifically, an element whose electric resistance (p) changes in accordance with a pressure (a) can be used for the sensor 802(g,h) (see FIG. 21D). Thus, the sensor 802(g,h) can sense the pushing depth.

### <Structure Example 2 of Input/Output Device>

The input/output device described in this embodiment includes a component 249 (see FIGS. 21A and 22A).

### <<Structure Example of Component 249>>

The component 249 overlaps with the sensing region 241 and has elasticity.

For example, an elastic body can be used for the component 249. Specifically, a spring, a plate spring, a rubber, a sponge, or the like can be used for the component 249.

Thus, the sensor 802(g,h) can sense the pushing depth. Alternatively, a user can feel the force corresponding to the pushing depth with the pointer.

For example, the component in which snap-through buckling occurs can be employed for the component 249. Specifically, a dome-shaped component, for example, can be employed as the component 249 (see FIG. 22B).

The component 249 has a mode 1 in which the component 249 is stable in a region with small distortion c and a mode 2 in which the component 249 is stable in a region with large distortion c (see FIGS. 22C and 22D). The component 249 changes from the mode 1 to the mode 2 at the buckling point (see FIG. 22D). Furthermore, the component 249 reversibly changes from the mode 2 to the mode 1 when the distortion is eliminated.

Thus, the sensor 802(g,h) can sense the force corresponding to the pushing depth up to the buckling point. Alternatively, a user can obtain a sense of the force. When the force exceeds the buckling point, the user can have a click feeling. Alternatively, what is called a tactile switch can be provided. Alternatively, when the user releases the pushed pointer, the component in which snap-through buckling occurs can return to the original mode.

Note that the sensing region 241 can be provided to overlap with the component in which snap-through buckling occurs, the region 231 can be provided to overlap with the sensing region 241, and an image used for operation can be displayed at a position overlapping with the component in which snap-through buckling occurs. For example, a layout that is suitably used for a keyboard can be employed for the layout of the components in which snap-through buckling occurs. Alternatively, a layout that is suitably used for a home button can be employed for the layout of the components in which snap-through buckling occurs.

Thus, the displayed images used for operation can be pressed. Alternatively, the user can have a click feeling when pressing the images.

Furthermore, the component 249 can have a region where a plurality of components in which snap-through buckling occurs are entirely provided on the whole area. The sensing region 241 can be provided to overlap with the region, the region 231 can be provided to overlap with the sensing region 241, and the image used for operation can be displayed at a position that overlaps with the region, the whole area of which is provided with the plurality of components.

Thus, images which are used for operation and can provide a click feeling by being pressed can be freely laid out.

Note that a sensor portion 250 may be provided to overlap with the input/output device described in this embodiment. For example, a pressure-sensitive switch can be used for the sensor portion 250. Specifically, a conductive material is used for a dome-shaped component in which snap-through buckling occurs, and the dome-shaped component can be used at a contact point with the pressure-sensitive switch. Thus, what is called a membrane switch can be provided. Alternatively, a switch that provides a click feeling can be provided. Alternatively, what is called a tactile switch can be provided.

Note that this embodiment can be combined with any of the other embodiments in this specification as appropriate.

### Embodiment 9

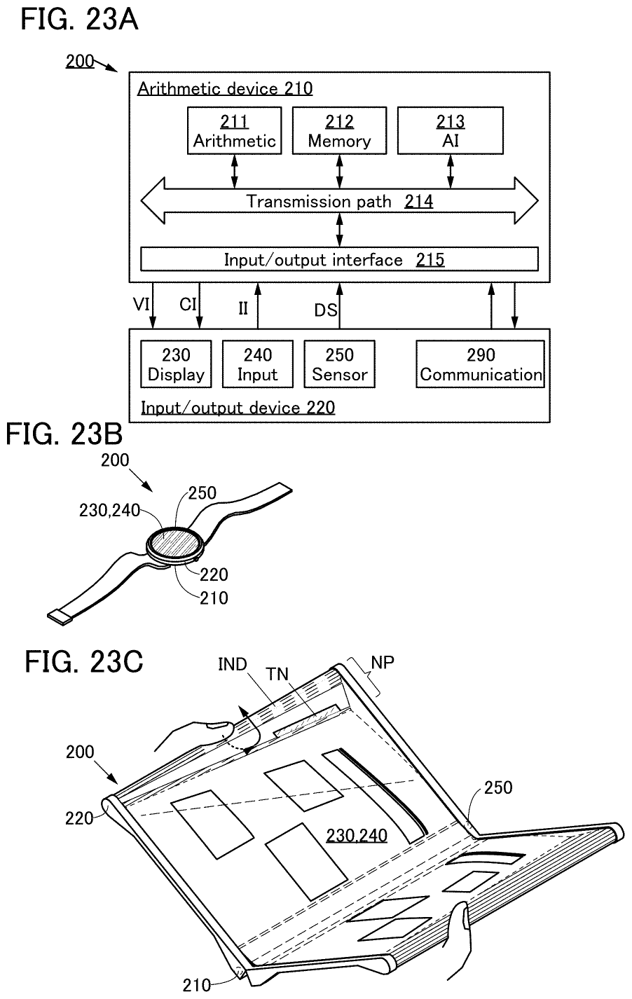

In this embodiment, a structure of a data processing device of one embodiment of the present invention will be described with reference to FIGS. 23A to 23C, FIGS. 24A and 24B, and FIGS. 25A to 25C.

FIG. 23A is a block diagram illustrating a structure of a data processing device of one embodiment of the present invention. FIGS. 23B and 23C are projection views each illustrating an example of the appearance of a data processing device.

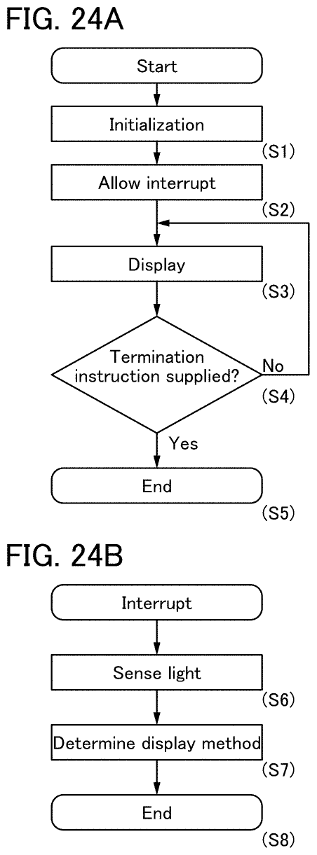

FIGS. 24A and 24B are flow charts illustrating a program of one embodiment of the present invention. FIG. 24A is a flow chart illustrating main processing of the program of one embodiment of the present invention. FIG. 24B is a flow chart illustrating interrupt processing.

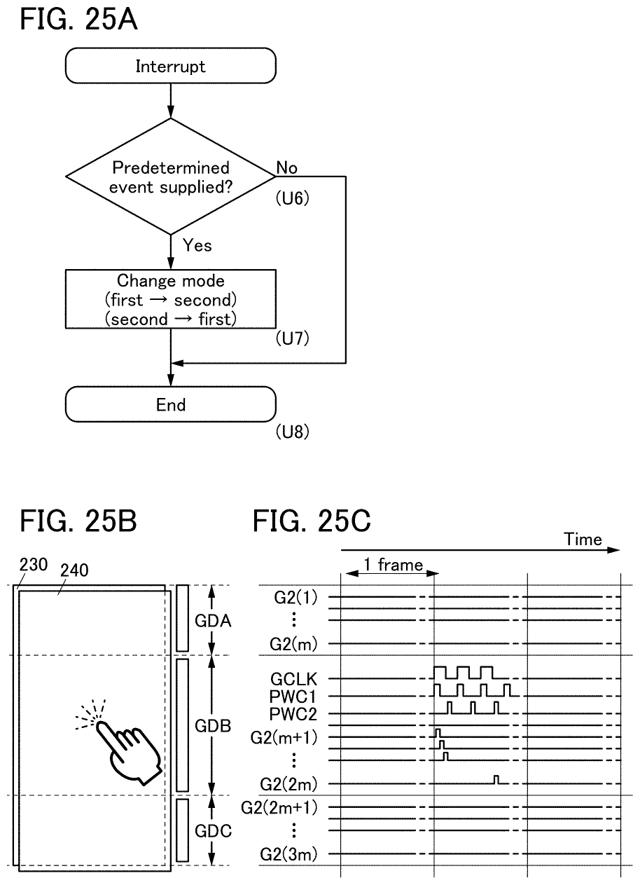

FIGS. 25A to 25C illustrate a program of one embodiment of the present invention. FIG. 25A is a flow chart illustrating interrupt processing of the program of one embodiment of the present invention. FIG. 25B is a schematic view illustrating handling of a data processing device of one embodiment of the present invention, and FIG. 25C is a timing chart illustrating operation of the data processing device of one embodiment of the present invention.

### <Structure Example 1 of Data Processing Device>

The data processing device described in this embodiment includes an arithmetic device 210 and an input/output device 220 (see FIG. 23A). The input/output device 220 is electrically connected to the arithmetic device 210. The data processing device 200 can include a housing (see FIG. 23B and FIG. 23C).

### <<Structure Example 1 of Arithmetic Device 210>>

The arithmetic device 210 is supplied with input data II or sensing data DS. The arithmetic device 210 generates the control data CI and the image data VI on the basis of the input data II or the sensing data DS, and supplies the control data CI and the image data VI.

The arithmetic device 210 includes an arithmetic unit 211 and a memory unit 212. The arithmetic device 210 also includes a transmission path 214 and an input/output interface 215.

The transmission path 214 is electrically connected to the arithmetic unit 211, the memory unit 212, and the input/output interface 215.

### <<Arithmetic Unit 211>>

The arithmetic unit 211 has a function of executing a program, for example.

### <<Memory Unit 212>>

The memory unit 212 has a function of, for example, storing a program executed by the arithmetic unit 211, initial data, setting data, an image, or the like.

Specifically, a hard disk, a flash memory, a memory using a transistor including an oxide semiconductor, or the like can be used.

### <<Input/Output Interface 215 and Transmission Path 214>>

The input/output interface 215 includes a terminal or a wiring and has a function of supplying data and receiving data. For example, the input/output interface 215 can be electrically connected to the transmission path 214. Moreover, the input/output interface 215 can be electrically connected to the input/output device 220.

The transmission path 214 includes a wiring and has a function of supplying data and receiving data. For example, the transmission path 214 can be electrically connected to the input/output interface 215. In addition, the transmission path 214 can be electrically connected to the arithmetic unit 211, the memory unit 212, or the input/output interface 215.

### <<Structure Example of Input/Output Device 220>>

The input/output device 220 supplies the input data II and the sensing data DS. The input/output device 220 is supplied with the control data CI and the image data VI (see FIG. 23A).

For example, a keyboard scan code, positional data, data on button handling, sound data, or image data can be used as the input data II. For example, data on illuminance, attitude, acceleration, direction, pressure, temperature, or humidity of the environment where the data processing device 200 is used, for instance, can be used as the sensing data DS.

For example, a signal for controlling the luminance, a signal for controlling the color saturation, or a signal for controlling the hue to display the image data VI can be used as the control data CI. Alternatively, a signal for changing part of display based on the image data VI can be used as the control data CI.

The input/output device 220 includes the display portion 230, the input portion 240, and a sensor portion 250. For example, the input/output device described in Embodiment 8 can be used as the input/output device 220. The input/output device 220 can include a communication portion 290.

### <<Structure Example of Display Portion 230>>

The display portion 230 displays the image data VI on the basis of the control data CI.

The display portion 230 includes the control portion 238, the driver circuit GD, the driver circuit SD, and the functional panel 700 (see FIG. 19A). For example, the display device described in Embodiment 7 can be used in the display portion 230.

### <<Structure Example of Input Portion 240>>

The input portion 240 generates the input data II. The input portion 240 has a function of supplying positional data P1, for example.

For example, a human interface or the like can be used as the input portion 240 (see FIG. 23A). Specifically, a keyboard, a mouse, a touch sensor, a microphone, a camera, or the like can be used as the input portion 240.

A touch sensor having a region overlapping with the display portion 230 can be used. Note that an input/output device that includes the display portion 230 and a touch sensor having a region overlapping with the display portion 230 can be referred to as a touch panel or a touch screen.

For example, a user can make various gestures (e.g., tap, drag, swipe, and pinch in) using a finger on the touch panel as a pointer.

The arithmetic device 210, for example, analyzes data on the position, track, or the like of the finger on the touch panel and determines that a predetermined gesture is supplied when the analysis results meet predetermined conditions. Therefore, the user can supply a certain operating instruction associated with a predetermined gesture by using the gesture.

For instance, the user can supply a scrolling instruction for changing the position where image data is displayed, by using a gesture of touching and moving a finger on the touch panel.

The user can supply a dragging instruction for pulling out and displaying a navigation panel NP at an edge portion of the region 231, by using a gesture of moving a finger touching the edge portion of the region 231 (see FIG. 23C). Moreover, the user can supply a leafing through instruction for displaying index images IND, some parts of other pages, or thumbnail images TN of other pages in an predetermined order on the navigation panel NP so that the user can flip through these images, by using a gesture of moving the position where a finger presses hard or by using the pressure of pressing the finger. Consequently, the user can turn the pages of an e-book like flipping through the pages of a paper book. Moreover, the user can search a given page with the aid of the thumbnail images TN or the index images IND.

### <<Structure Example of Sensor Portion 250>>

The sensor portion 250 generates the sensing data DS. The sensor portion 250 has a function of sensing the illuminance of the environment where the data processing device 200 is used and a function of supplying illuminance data, for example.

The sensor portion 250 has a function of sensing the ambient conditions and supplying the sensing data. Specifically, the sensor portion 250 can supply illuminance data, attitude data, acceleration data, direction data, pressure data, temperature data, humidity data, or the like.

For example, a photosensor, an attitude sensor, an acceleration sensor, a direction sensor, a global positioning system (GPS) signal receiving circuit, a pressure-sensitive switch, a pressure sensor, a temperature sensor, a humidity sensor, or a camera can be used as the sensor portion 250.

### <<Communication Portion 290>>

The communication portion 290 has a function of supplying data to a network and acquiring data from a network.

### <<Housing>>

The housing has a function of housing the input/output device 220 or the arithmetic device 210. Alternatively, the housing has a function of supporting the display portion 230 or the arithmetic device 210.

Accordingly, the control data can be generated on the basis of the input data or the sensing data. Alternatively, the image data can be displayed on the basis of the input data or the sensing data. Alternatively, the data processing device is capable of operating with knowledge of the intensity of light that the housing of the data processing device receives in the environment where the data processing device is used. Alternatively, the user of the data processing device can select a display method. Consequently, a novel data processing device that is highly convenient, useful, or reliable can be provided.

Note that in some cases, these components cannot be clearly distinguished from each other and one component may also serve as another component or include part of another component. For example, a touch panel in which a touch sensor overlaps with a display panel serves as an input portion as well as a display portion.

### <<Structure Example 2 of Arithmetic Device 210>>

The arithmetic device 210 includes an artificial intelligence unit 213 (see FIG. 23A).

The artificial intelligence unit 213 is supplied with the input data II or the sensing data DS, and infers the control data CI on the basis of the input data II or the sensing data DS. Moreover, the artificial intelligence unit 213 supplies the control data CI.

In this manner, the control data CI for performing display which the user finds suitable can be generated. Alternatively, it is possible to perform display which the user finds suitable. Alternatively, the control data CI for performing display which the user finds comfortable can be generated. Alternatively, it is possible to perform display which the user finds comfortable. Consequently, a novel data processing device that is highly convenient, useful, or reliable can be provided.

### [Natural Language Processing on Input Data II]

Specifically, the artificial intelligence unit 213 can perform natural language processing on the input data II and extract one feature from the whole input data II. For example, the artificial intelligence unit 213 can infer emotion or the like in the input data II and regard the inference as a feature. The artificial intelligence unit 213 can also infer the color, design, font, or the like empirically felt suitable for the feature. The artificial intelligence unit 213 can also generate data specifying the color, design, or font of a letter or data specifying the color or design of the background, and use the generated data as the control data CI.

Specifically, the artificial intelligence unit 213 can perform natural language processing on the input data II and extract some words included in the input data II. For example, the artificial intelligence unit 213 can extract expressions including a grammatical error, a factual error, emotion, or the like. Moreover, the artificial intelligence unit 213 can generate and use the control data CI for displaying extracted part in the color, design, font, or the like different from those of another part.

### [Image Processing on Input Data II]

Specifically, the artificial intelligence unit 213 can perform image processing on the input data II and extract one feature from the input data II. For example, the artificial intelligence unit 213 can infer the age where the input data II was captured, whether the input data II was captured indoors or outdoors, or whether the input data II was captured in the daytime or at night, for example, and regard the inference as a feature. The artificial intelligence unit 213 can also infer the color tone empirically felt suitable for the feature and generate the control data CI for using the color tone for display. Specifically, data specifying color (e.g., full color, monochrome, or sepia) used for expressing a gradation can be used as the control data CI.

Specifically, the artificial intelligence unit 213 can perform image processing on the input data II and extract some images included in the input data II. For example, the artificial intelligence unit 213 can generate the control data CI for displaying a boundary between one part and another part of the extracted image. Specifically, the artificial intelligence unit 213 can generate the control data CI for displaying a rectangle surrounding part of the extracted image.

### [Inference Using Sensing Data DS]

Specifically, the artificial intelligence unit 213 can make inference RI with the use of the sensing data DS. Alternatively, the artificial intelligence unit 213 can generate the control data CI on the basis of the inference RI so that the user of the data processing device 200 can feel comfortable.

Specifically, the artificial intelligence unit 213 can generate the control data CI for adjusting display brightness on the basis of the ambient illuminance or the like to provide comfortable display brightness. The artificial intelligence unit 213 can also generate the control data CI for adjusting volume on the basis of the ambient noise or the like to provide comfortable volume.

As the control data CI, a clock signal, a timing signal, or the like that is supplied to the control portion 238 included in the display portion 230 can be used. A clock signal, a timing signal, or the like that is supplied to a control portion included in the input portion 240 can also be used as the control data CI.

### <Structure Example 2 of Data Processing Device>

Another structure of the data processing device of one embodiment of the present invention will be described with reference to FIGS. 24A and 24B.

### <<Program>>

A program of one embodiment of the present invention includes the following steps (see FIG. 24A).

### [First Step]

In a first step, the setting is initialized (see S1 in FIG. 24A).

For example, predetermined image data that is to be displayed on start-up and data for determining a predetermined mode of displaying the image data and a predetermined method of displaying the image data are acquired from the memory unit 212. Specifically, still image data or moving image data can be used as the predetermined image data. Furthermore, a first mode or a second mode can be used as the predetermined mode.

### [Second Step]

In a second step, interrupt processing is allowed (see S2 in FIG. 24A). Note that an arithmetic device allowed to execute the interrupt processing can perform the interrupt processing in parallel with the main processing. The arithmetic device which has returned from the interrupt processing to the main processing can reflect the results of the interrupt processing in the main processing.

The arithmetic device may execute the interrupt processing when a counter has an initial value, and the counter may be set at a value other than the initial value when the arithmetic device returns from the interrupt processing. Thus, the interrupt processing is always ready to be executed after the program is started up.

### [Third Step]

In a third step, image data is displayed in a predetermined mode or a predetermined display method selected in the first step or the interrupt processing (see S3 in FIG. 24A). Note that the predetermined mode identifies a mode for displaying the image data, and the predetermined display method identifies a method of displaying the image data. For example, the image data VI can be used as data to be displayed.

For example, one method of displaying the image data VI can be associated with the first mode. Another method of displaying the image data VI can be associated with the second mode. Thus, a display method can be selected on the basis of the selected mode.

### <<First Mode>>

Specifically, a method of supplying selection signals to a scan line at a frequency of 30 Hz or more, preferably 60 Hz or more and performing display in accordance with the selection signals can be associated with the first mode.

For example, the supply of selection signals at a frequency of 30 Hz or more, preferably 60 Hz or more enables motion in a moving image to be displayed smoothly.

For example, refreshing an image at a frequency of 30 Hz or more, preferably 60 Hz or more allows the data processing device 200 that the user is using to display an image smoothly following the user's operation.

### <<Second Mode>>

Specifically, a method of supplying selection signals to a scan line at a frequency less than 30 Hz, preferably less than 1 Hz, further preferably less than once a minute and performing display in accordance with the selection signals can be associated with the second mode.

The supply of selection signals at a frequency less than 30 Hz, preferably less than 1 Hz, further preferably less than once a minute allows display with flickering reduced. Furthermore, power consumption can be reduced.

For example, when the data processing device 200 is used in a clock or a watch, the display can be refreshed once a second, once a minute, or the like.

For example, when a light-emitting element is used as a display element, the light-emitting element can be made to emit light in a pulsed manner to display image data. Specifically, an organic EL element can be made to emit light in a pulsed manner, and its afterglow can be used for display. Since an organic EL element has excellent frequency characteristics, time for driving the light-emitting element can be shortened, and thus power consumption can be reduced in some cases. Alternatively, heat generation can be inhibited, and thus the deterioration of the light-emitting element can be suppressed in some cases.

### [Fourth Step]

In a fourth step, the program moves to a fifth step when a termination instruction has been supplied, whereas the program moves to the third step when the termination instruction has not been supplied (see S4 in FIG. 24A).

For example, a termination instruction supplied in the interrupt processing can be used to determine the next step.

### [Fifth Step]

In the fifth step, the program terminates (see S5 in FIG. 24A).

### <<Interrupt Processing>>

The interrupt processing includes sixth to eighth steps described below (see FIG. 24B).

### [Sixth Step]

In the sixth step, the illuminance of the environment where the data processing device 200 is used is sensed using the sensor portion 250, for example (see S6 in FIG. 24B). Note that the color temperature or chromaticity of ambient light may be sensed instead of the illuminance of the environment.

### [Seventh Step]

In the seventh step, a display method is determined on the basis of the sensed illuminance data (see S7 in FIG. 24B). For example, a display method is determined such that the brightness of display is not too bright or too dark.

In the case where the color temperature or chromaticity of the ambient light is sensed in the sixth step, the color of display may be adjusted.

### [Eighth Step]

In the eighth step, the interrupt processing terminates (see S8 in FIG. 24B).

### <Structure Example 3 of Data Processing Device>

Another structure of the data processing device of one embodiment of the present invention will be described with reference to FIGS. 25A to 25C.

FIG. 25A is a flow chart illustrating a program of one embodiment of the present invention. The interrupt processing in the flow chart in FIG. 25A is different from that in FIG. 24B.

Note that the structure example 3 of the data processing device is different from the interrupt processing in FIG. 24B in that the interrupt processing includes a step of changing a mode on the basis of a supplied predetermined event. Here, the differences will be described in detail below, and the above description is referred to for similar portions.

### <<Interrupt Processing>>

The interrupt processing includes the following sixth to eighth steps (see FIG. 25A).

### [Sixth Step]

In the sixth step, the processing proceeds to the seventh step when a predetermined event has been supplied, whereas the processing proceeds to the eighth step when the predetermined event has not been supplied (see U6 in FIG. 25A). For example, whether the predetermined event is supplied in a predetermined period or not can be a branch condition. Specifically, the predetermined period can be a period longer than 0 seconds and 5 seconds or less, 1 second or less, 0.5 seconds or less, preferably 0.1 seconds or less.

### [Seventh Step]

In the seventh step, the mode is changed (see U7 in FIG. 25A). Specifically, the mode is changed from the first mode to the second mode, or the mode is changed from the second mode to the first mode.

For example, a display mode of part of a region in the display portion 230 can be changed. Specifically, it is possible to change a display mode of a region where one driver circuit in the display portion 230 including a driver circuit GDA, a driver circuit GDB, and a driver circuit GDC supplies a selection signal (see FIG. 25B).

For example, the display mode of the region where a selection signal is supplied from the driver circuit GDB can be changed when a predetermined event is supplied to the input portion 240 in a region overlapping with the region where a selection signal is supplied from the driver circuit GDB (see FIGS. 25B and 25C). Specifically, the frequency of the selection signal supplied from the driver circuit GDB can be changed in accordance with a “tap” event supplied to a touch panel with a finger or the like.

A signal GCLK is a clock signal for controlling the operation of the driver circuit GDB, and signals PWC1 and PWC2 are pulse width control signals for controlling the operation of the driver circuit GDB. The driver circuit GDB supplies selection signals to conductive films G2(m+1) to G2(2m) on the basis of the signals GCLK, PWC1, PWC2, and the like.

Thus, for example, the driver circuit GDB can supply selection signals without supply of selection signals from the driver circuits GDA and GDC. Alternatively, the display of the region where selection signals are supplied from the driver circuit GDB can be refreshed without any change in the display of regions where selection signals are supplied from the driver circuits GDA and GDC. Alternatively, power consumed by the driver circuits can be reduced.

### [Eighth Step]

In the eighth step, the interrupt processing terminates (see U8 in FIG. 25A). Note that the interrupt processing may be repeatedly executed in a period during which the main processing is executed.

### <<Predetermined Event>>

For example, the following events can be used: events supplied using a pointing device such as a mouse (e.g., click and drag) and events supplied to a touch panel with a finger or the like used as a pointer (e.g., tap, drag, and swipe).

For example, the position of a slide bar pointed by a pointer, the swipe speed, and the drag speed can be used as parameters assigned to an instruction associated with a predetermined event.

For example, data sensed by the sensor portion 250 is compared to a predetermined threshold value, and the compared results can be used for the event.

Specifically, a pressure sensor or the like in contact with a button or the like that can be pushed in a housing can be used as the sensor portion 250.

<<Instruction Associated with Predetermined Event>>

For example, a termination instruction can be associated with a predetermined event.

For example, a page-turning instruction for switching displayed image data from one to another can be associated with a predetermined event. Note that a parameter determining the page-turning speed or the like when the page-turning instruction is executed can be supplied using the predetermined event.

For example, a scroll instruction for moving the position of displayed part of image data and displaying another part continuing from that part can be associated with a predetermined event. Note that a parameter determining the moving speed of the display position, for instance, when the scroll instruction is executed can be supplied using the predetermined event.

For example, an instruction for setting the display method or an instruction for generating image data can be associated with a predetermined event. Note that a parameter determining the brightness of a generated image can be associated with the predetermined event. A parameter determining the brightness of a generated image may be determined on the basis of ambient brightness sensed by the sensor portion 250.

For example, an instruction for acquiring data distributed via a push service using the communication portion 290 can be associated with a predetermined event.

Note that positional data sensed by the sensor portion 250 may be used to determine the presence or absence of a qualification for acquiring data. Specifically, the user may be considered to have a qualification for acquiring data when the user is in a predetermined class room, school, conference room, office, building, or the like. Accordingly, for example, the data processing device 200 that receives educational materials distributed in a classroom of a school or a university can be used as a schoolbook or the like (see FIG. 23C). Alternatively, materials distributed in a company's conference room, for instance, can be received and used for a conference material.

### <Structure Example 4 of Data Processing Device>

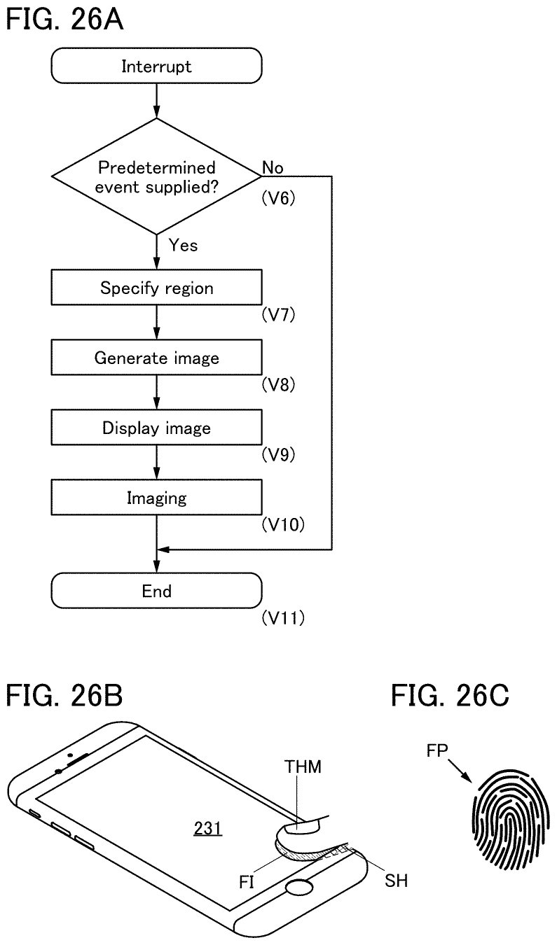

Another structure of the data processing device of one embodiment of the present invention will be described with reference to FIGS. 26A to 26C.

FIG. 26A is a flow chart illustrating a program of one embodiment of the present invention. The interrupt processing in the flow chart in FIG. 26A is different from that in FIG. 24B. FIG. 26B is a schematic diagram illustrating the operation of the program illustrated in FIG. 26A. FIG. 26C is a schematic diagram of a captured fingerprint.

Note that the structure example 4 of the data processing device described with FIG. 26A is different from the structure example described with FIG. 24B in the interrupt processing. Specifically, the interrupt processing in this example includes a step of specifying a region, a step of generating an image, a step of displaying the image, and a step of taking an image on the basis of a supplied predetermined event. Here, the differences will be described in detail below, and the above description is referred to for similar portions.

### <<Interrupt Processing>>

The interrupt processing includes sixth to eleventh steps (see FIG. 26A).

### [Sixth Step]

In the sixth step, the processing proceeds to the seventh step when a predetermined event has been supplied, whereas the processing proceeds to the eleventh step when the predetermined event has not been supplied (see V6 in FIG. 26A).

The predetermined event can be supplied with the sensor portion 250, for example. Specifically, a motion such as lifting of the data processing device can be used as the predetermined event. For example, a motion of the data processing device can be sensed using an angular sensor or an acceleration sensor. Alternatively, contact or proximity of an object such as a finger can be sensed using a touch sensor.

### [Seventh Step]

In the seventh step, a first region SH is specified (see V7 in FIG. 26A).

For example, a region where an object such as a finger touches or approaches the input/output device 220 of one embodiment of the present invention can be the first region SH. Alternatively, a region that is set in advance by the user or the like can be used as the first region SH.

Specifically, an image of a finger THM or the like that touches or approaches the functional panel of one embodiment of the present invention is taken using the pixel 703(i,j) and subjected to image processing, whereby the first region SH can be specified (see FIG. 26B).

For example, an image of a shadow caused when external light is blocked by contact or proximity of an object such as the finger THM is taken using the pixel 70301) in the functional panel of one embodiment of the present invention and subjected to image processing, whereby the first region SH can be specified.

Alternatively, with the use of the pixel 703(i,j) in the functional panel of one embodiment of the present invention, an object such as the finger THM that touches or approaches the functional panel is irradiated with light, and an image of light reflected by the object is taken using the pixel 703(i,j) and subjected to image processing, whereby the first region SH can be specified.

Alternatively, a region where an object such as the finger THM touches can be specified as the first region SH by a touch sensor.

### [Eighth Step]

In the eighth step, an image FI including a second region and a third region is generated in accordance with the first region SH (see V8 in FIGS. 26A and 26B). For example, the shape of the first region SH is used as the shape of the second region, and a region excluding the first region SH is used as the third region.

### [Ninth Step]

In the ninth step, the image FI is displayed so that the second region overlaps with the first region SH (see V9 in FIGS. 26A and 26B).

For example, an image signal is generated from the image FI and supplied to the region 231, and light is emitted from the pixel 703(i,j). Alternatively, in a period during which the first selection signal is supplied to the conductive film G1 (i), the generated image signal is supplied to the conductive film S1g(j), and the image signal can be written to the pixel 703(i,j). Alternatively, the generated image signal is supplied to the conductive film S1g(j) and the conductive film S2g(j), and an enhanced image signal can be written to the pixel 703(i,j). Alternatively, the use of an enhanced image signal enables display with higher luminance.

Thus, the image FI can be displayed to overlap with the region 231 where an object such as a finger touches or the first region SH where the object approaches. Alternatively, the region where an object such as a finger touches can be irradiated with light with the use of the pixel 703(i,j). Alternatively, a touching or approaching object such as the finger THM can be illuminated. Alternatively, the user can be encouraged to make an object such as a finger touch or approach a region that is set in advance by the user or the like.

### [Tenth Step]

In the tenth step, an image of an object that touches or approaches the first region SH is taken while the image FI is displayed (see V10 in FIGS. 26A and 26B).

For example, an image of the finger THM or the like approaching the region 231 is taken while the finger THM or the like is irradiated with light. Specifically, an image of a fingerprint FP of the finger THM in contact with the region 231 can be taken (see FIG. 26C).

For example, the supply of the first selection signal can be stopped while an image is displayed with the pixel 703(i,j). For example, an image can be taken using the pixel 70301) while the supply of the first selection signal to the pixel circuit 530G(i,j) is stopped.

Accordingly, an image of a touching or approaching object such as a finger can be taken while the object is illuminated. Alternatively, an image can be taken in a period during which the first selection signal is not supplied. Alternatively, noise in imaging can be suppressed. Alternatively, a clear image of a fingerprint can be obtained. Alternatively, an image that can be used for the authentication of the user can be obtained. Alternatively, a clear image of the fingerprint of a finger that touches any position in the region 231 can be taken. Consequently, a novel data processing device that is highly convenient, useful, or reliable can be provided.

### [Eleventh Step]

In the eleventh step, the interrupt processing terminates (see V11 in FIG. 26A).

Note that this embodiment can be combined with any of the other embodiments in this specification as appropriate.

### Embodiment 10

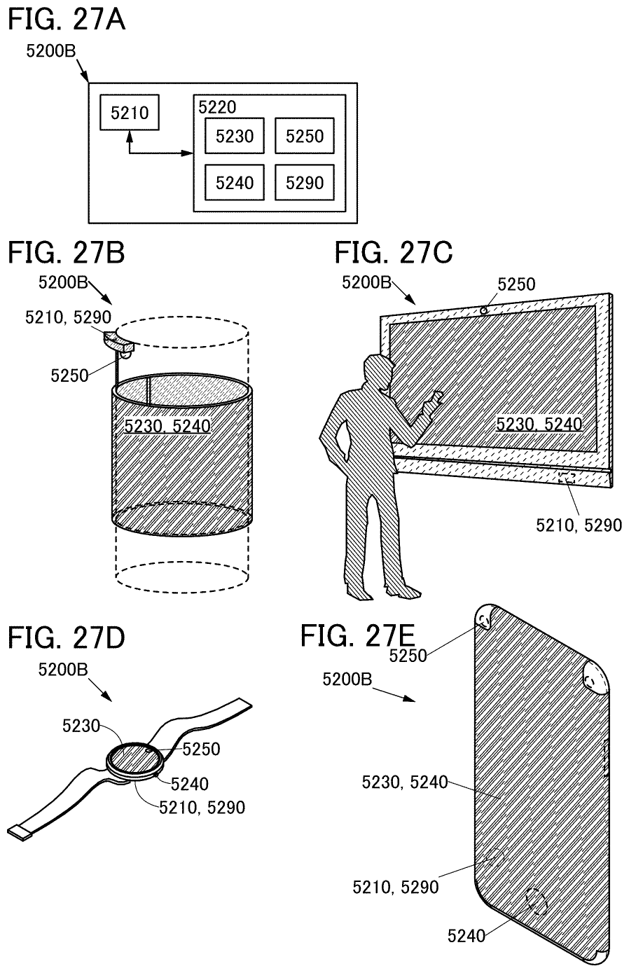

In this embodiment, a structure of a data processing device of one embodiment of the present invention will be described with reference to FIGS. 27A to 27E, FIGS. 28A to 28E, and FIGS. 29A and 29B.

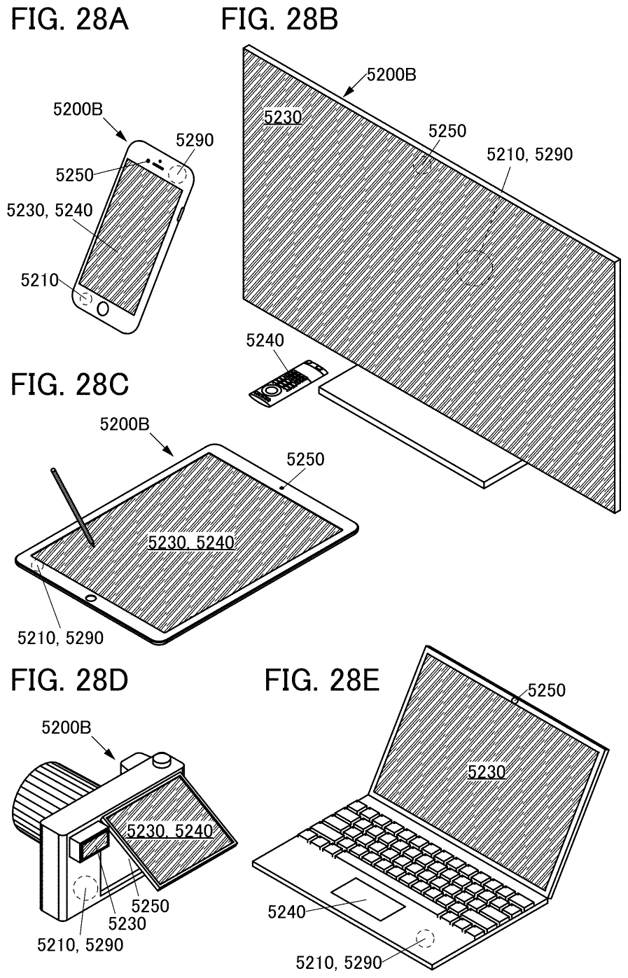

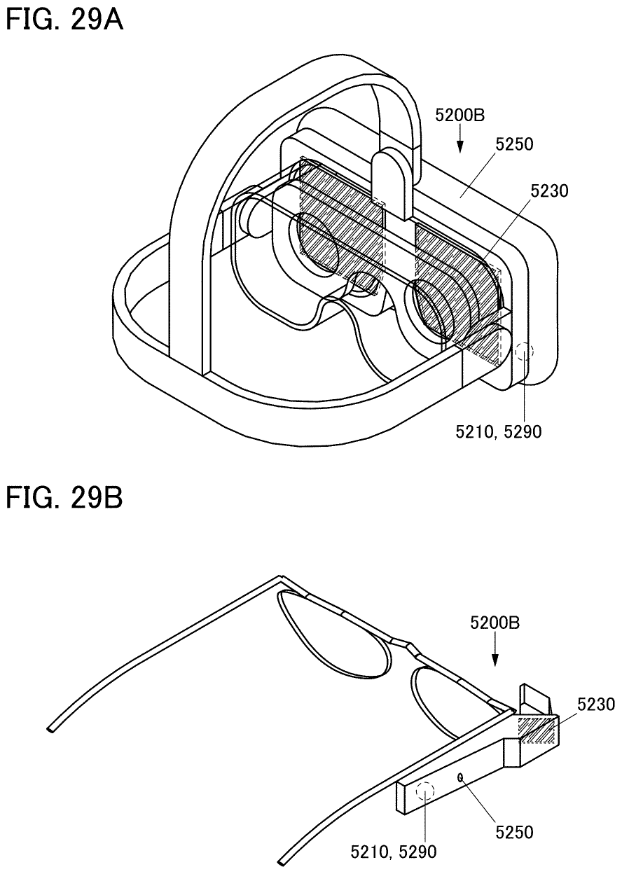

FIGS. 27A to 27E, FIGS. 28A to 28E, and FIGS. 29A and 29B illustrate structures of a data processing device of one embodiment of the present invention. FIG. 27A is a block diagram of a data processing device, and FIGS. 27B to 27E are perspective views each illustrating a structure of the data processing device. FIGS. 28A to 28E are perspective views each illustrating a structure of the data processing device. FIGS. 29A and 29B are perspective views each illustrating a structure of the data processing device.

### <Data Processing Device>

A data processing device 5200B described in this embodiment includes an arithmetic device 5210 and an input/output device 5220 (see FIG. 27A).

The arithmetic device 5210 has a function of receiving handling data and a function of supplying image data on the basis of the handling data.

The input/output device 5220 includes a display portion 5230, an input portion 5240, a sensor portion 5250, and a communication portion 5290 and has a function of supplying handling data and a function of receiving image data. The input/output device 5220 also has a function of supplying sensing data, a function of supplying communication data, and a function of receiving communication data.

The input portion 5240 has a function of supplying handling data. For example, the input portion 5240 supplies handling data on the basis of handling by a user of the data processing device 5200B.

Specifically, a keyboard, a hardware button, a pointing device, a touch sensor, an illuminance sensor, an imaging device, an audio input device, an eye-gaze input device, an attitude sensing device, or the like can be used as the input portion 5240.

The display portion 5230 includes a functional panel and has a function of displaying image data. For example, the functional panel described in any of Embodiments 1 to 5 can be used in the display portion 5230.

The sensor portion 5250 has a function of supplying sensing data. For example, the sensor portion 5250 has a function of sensing a surrounding environment where the data processing device is used and supplying sensing data.

Specifically, an illuminance sensor, an imaging device, an attitude sensing device, a pressure sensor, a human motion sensor, or the like can be used as the sensor portion 5250.

The communication portion 5290 has a function of receiving and supplying communication data. For example, the communication portion 5290 has a function of being connected to another electronic device or a communication network through wireless communication or wired communication. Specifically, the communication portion 5290 has a function of wireless local area network communication, telephone communication, or near field communication, for example.

### <<Structure Example 1 of Data Processing Device>>

For example, the display portion 5230 can have an outer shape along a cylindrical column (see FIG. 27B). The data processing device has a function of changing its display method in accordance with the illuminance of a usage environment. In addition, the data processing device has a function of changing the displayed content when sensing the existence of a person. This allows the data processing device to be provided on a column of a building, for example. The data processing device can display advertising, guidance, or the like. The data processing device can be used for digital signage or the like.

### <<Structure Example 2 of Data Processing Device>>

For example, the data processing device has a function of generating image data on the basis of the path of a pointer used by a user (see FIG. 27C). Specifically, a functional panel with a diagonal size of 20 inches or longer, preferably 40 inches or longer, further preferably 55 inches or longer can be used. Alternatively, a plurality of functional panels can be arranged and used as one display region. Alternatively, a plurality of functional panels can be arranged and used as a multiscreen. Thus, the data processing device can be used for an electronic blackboard, an electronic bulletin board, or digital signage, for example.

### <<Structure Example 3 of Data Processing Device>>

The data processing device can receive data from another device, and the data can be displayed on the display portion 5230 (see FIG. 27D). Moreover, several options can be displayed. The user can choose some from the options and send a reply to the data transmitter. As another example, the data processing device has a function of changing its display method in accordance with the illuminance of a usage environment. Thus, it is possible to obtain a smartwatch with reduced power consumption, for example. As another example, it is possible to obtain a smartwatch which can display an image such that the smartwatch can be suitably used in an environment under strong external light, e.g., outdoors in fine weather.

### <<Structure Example 4 of Data Processing Device>>

For example, the display portion 5230 has a surface gently curved along a side surface of a housing (see FIG. 27E). The display portion 5230 includes a functional panel that is capable of displaying an image on the front surface, the side surfaces, the top surface, and the rear surface, for example. Thus, it is possible to obtain a mobile phone that can display image data on not only its front surface but also its side surfaces, top surface, and rear surface, for example.

### <<Structure Example 5 of Data Processing Device>>

For example, the data processing device can receive data via the Internet and display the data on the display portion 5230 (see FIG. 28A). The user can check a created message on the display portion 5230 or send the created message to another device. As another example, the data processing device has a function of changing its display method in accordance with the illuminance of a usage environment. Thus, it is possible to obtain a smartphone with reduced power consumption. Alternatively, for example, it is possible to obtain a smartphone which can display an image such that the smartphone can be suitably used in an environment under strong external light, e.g., outdoors in fine weather.

### <<Structure Example 6 of Data Processing Device>>

A remote controller can be used as the input portion 5240 (see FIG. 28B). For example, the data processing device can receive data from a broadcast station or via the Internet and display the data on the display portion 5230. Alternatively, the data processing device can take an image of the user with the sensor portion 5250 and transmit the image of the user. The data processing device can acquire a viewing history of the user and provide it to a cloud service. The data processing device can acquire recommendation data from a cloud service and display the data on the display portion 5230. A program or a moving image can be displayed on the basis of the recommendation data. As another example, the data processing device has a function of changing its display method in accordance with the illuminance of a usage environment. Accordingly, for example, it is possible to obtain a television system which can display an image such that the television system can be suitably used even when irradiated with strong external light that enters the room from the outside in fine weather.

### <<Structure Example 7 of Data Processing Device>>

For example, the data processing device can receive educational materials via the Internet and display them on the display portion 5230 (see FIG. 28C). The user can input an assignment with the input portion 5240 and send it via the Internet. The user can obtain a corrected assignment or the evaluation from a cloud service and have it displayed on the display portion 5230. The user can select suitable educational materials on the basis of the evaluation and have them displayed.

For example, the display portion 5230 can perform display using an image signal received from another data processing device. When the data processing device is placed on a stand or the like, the display portion 5230 can be used as a sub-display. Thus, for example, it is possible to obtain a tablet computer which can display an image such that the tablet computer is favorably used even in an environment with intense external light, e.g., in the open air under fine weather.

### <<Structure Example 8 of Data Processing Device>>

The data processing device includes, for example, a plurality of display portions 5230 (see FIG. 28D). For example, the display portion 5230 can display an image that the sensor portion 5250 is capturing. Alternatively, a captured image can be displayed on the sensor portion. Alternatively, a captured image can be decorated using the input portion 5240. Alternatively, a message can be attached to a captured image. Alternatively, a captured image can be transmitted via the Internet. Alternatively, the data processing device has a function of changing shooting conditions in accordance with the illuminance of a usage environment. Accordingly, for example, it is possible to obtain a digital camera that can display a subject such that an image is favorably viewed even in an environment with intense external light, e.g., in the open air under fine weather.

### <<Structure Example 9 of Data Processing Device>>

For example, the data processing device of this embodiment is used as a master and another data processing device is used as a slave, whereby the other data processing device can be controlled (see FIG. 28E). As another example, part of image data can be displayed on the display portion 5230 and another part of the image data can be displayed on a display portion of another data processing device. Image signals can be supplied to another data processing device. Alternatively, with the communication portion 5290, data to be written can be obtained from an input portion of another data processing device. Thus, a large display region can be utilized by using a portable personal computer, for example.

### <<Structure Example 10 of Data Processing Device>>

The data processing device includes, for example, the sensor portion 5250 that senses an acceleration or a direction (see FIG. 29A). The sensor portion 5250 can supply data on the position of the user or the direction in which the user faces. The data processing device can generate image data for the right eye and image data for the left eye in accordance with the position of the user or the direction in which the user faces. The display portion 5230 includes a display region for the right eye and a display region for the left eye. Thus, a virtual reality image that gives the user a sense of immersion can be displayed on a goggles-type data processing device, for example.

### <<Structure Example 11 of Data Processing Device>>

The data processing device includes, for example, an imaging device and the sensor portion 5250 that senses an acceleration or a direction (see FIG. 29B). The sensor portion 5250 can supply data on the position of the user or the direction in which the user faces. Alternatively, the data processing device can generate image data in accordance with the position of the user or the direction in which the user faces. Accordingly, the data can be shown together with a real-world scene, for example. Alternatively, an augmented reality image can be displayed on a glasses-type data processing device.

Note that this embodiment can be combined with any of the other embodiments in this specification as appropriate.

When this specification and the like explicitly states that X and Y are connected, the case where X and Y are electrically connected, the case where X and Y are functionally connected, and the case where X and Y are directly connected are regarded as being disclosed in this specification and the like. Accordingly, without limitation to a predetermined connection relation, for example, a connection relation shown in drawings or text, another connection relation is regarded as being disclosed in the drawings or the text.

Here, X and Y each denote an object (e.g., a device, an element, a circuit, a wiring, an electrode, a terminal, a conductive film, or a layer).

Examples of the case where X and Y are directly connected include the case where an element that allows electrical connection between X and Y (e.g., a switch, a transistor, a capacitor, an inductor, a resistor, a diode, a display element, a light-emitting element, or a load) is not connected between X and Y, and the case where X and Y are connected without the element that allows electrical connection between X and Y provided therebetween.

For example, in the case where X and Y are electrically connected, at least one element that enables electrical connection between X and Y (e.g., a switch, a transistor, a capacitor, an inductor, a resistor, a diode, a display element, a light-emitting element, or a load) can be connected between X and Y. Note that a switch is controlled to be turned on or off That is, a switch is turned on or off to determine whether current flows therethrough or not. Alternatively, a switch has a function of selecting and changing a current path. Note that the case where X and Y are electrically connected includes the case where X and Y are directly connected.

For example, in the case where X and Y are functionally connected, one or more circuits that enable functional connection between X and Y (e.g., a logic circuit such as an inverter, a NAND circuit, or a NOR circuit; a signal converter circuit such as a D/A converter circuit, an A/D converter circuit, or a gamma correction circuit; a potential level converter circuit such as a power supply circuit (e.g., a step-up circuit or a step-down circuit) or a level shifter circuit for changing the potential level of a signal; a voltage source; a current source; a switching circuit; an amplifier circuit such as a circuit that can increase signal amplitude, the amount of current, or the like, an operational amplifier, a differential amplifier circuit, a source follower circuit, or a buffer circuit; a signal generation circuit; a memory circuit; or a control circuit) can be connected between X and Y. For instance, even if another circuit is provided between X and Y, X and Y are regarded as being functionally connected when a signal output from X is transmitted to Y. Note that the case where X and Y are functionally connected includes the case where X and Y are directly connected and the case where X and Y are electrically connected.

Note that an explicit description “X and Y are electrically connected” means that the case where X and Y are electrically connected (i.e., the case where X and Y are connected with another element or another circuit provided therebetween), the case where X and Y are functionally connected (i.e., the case where X and Y are connected with another circuit provided therebetween), and the case where X and Y are directly connected (i.e., the case where X and Y are connected without another element or another circuit provided therebetween) are regarded as being disclosed in this specification and the like. That is, the explicit description “X and Y are electrically connected” is considered to be disclosure of the same contents as ones using a simple and explicit description “X and Y are connected” in this specification and the like.

For example, any of the following expressions can be used for the case where a source (or a first terminal or the like) of a transistor is electrically connected to X through (or not through) Z1 and a drain (or a second terminal or the like) of the transistor is electrically connected to Y through (or not through) Z2, or the case where a source (or a first terminal or the like) of a transistor is directly connected to one part of Z1 and another part of Z1 is directly connected to X while a drain (or a second terminal or the like) of the transistor is directly connected to one part of Z2 and another part of Z2 is directly connected to Y.

Examples of the expressions include “X, Y, a source (or a first terminal or the like) of a transistor, and a drain (or a second terminal or the like) of the transistor are electrically connected to each other, and X, the source (or the first terminal or the like) of the transistor, the drain (or the second terminal or the like) of the transistor, and Y are electrically connected to each other in this order”, “a source (or a first terminal or the like) of a transistor is electrically connected to X, a drain (or a second terminal or the like) of the transistor is electrically connected to Y, and X, the source (or the first terminal or the like) of the transistor, the drain (or the second terminal or the like) of the transistor, and Y are electrically connected to each other in this order”, and “X is electrically connected to Y through a source (or a first terminal or the like) and a drain (or a second terminal or the like) of a transistor, and X, the source (or the first terminal or the like) of the transistor, the drain (or the second terminal or the like) of the transistor, and Y are provided to be connected in this order”. When the connection order in a circuit configuration is defined by an expression similar to the above examples, a source (or a first terminal or the like) and a drain (or a second terminal or the like) of a transistor can be distinguished from each other to specify the technical scope.

Other examples of the expressions include “a source (or a first terminal or the like) of a transistor is electrically connected to X through at least a first connection path, the first connection path does not include a second connection path, the second connection path is a path through the transistor between the source (or the first terminal or the like) of the transistor and a drain (or a second terminal or the like) of the transistor, Z1 is on the first connection path, the drain (or the second terminal or the like) of the transistor is electrically connected to Y through at least a third connection path, the third connection path does not include the second connection path, and Z2 is on the third connection path”; and “a source (or a first terminal or the like) of a transistor is electrically connected to X through at least Z1 on a first connection path, the first connection path does not include a second connection path, the second connection path includes a connection path through the transistor, a drain (or a second terminal or the like) of the transistor is electrically connected to Y through at least Z2 on a third connection path, and the third connection path does not include the second connection path”. Still another example of the expression is “a source (or a first terminal or the like) of a transistor is electrically connected to X through at least Z1 on a first electrical path, the first electrical path does not include a second electrical path, the second electrical path is an electrical path from the source (or the first terminal or the like) of the transistor to a drain (or a second terminal or the like) of the transistor, the drain (or the second terminal or the like) of the transistor is electrically connected to Y through at least Z2 on a third electrical path, the third electrical path does not include a fourth electrical path, and the fourth electrical path is an electrical path from the drain (or the second terminal or the like) of the transistor to the source (or the first terminal or the like) of the transistor”. When the connection path in a circuit structure is defined by an expression similar to the above examples, a source (or a first terminal or the like) and a drain (or a second terminal or the like) of a transistor can be distinguished from each other to specify the technical scope.

Note that these expressions are examples, and there is no limitation on the expressions. Here, X, Y, Z1, and Z2 each denote an object (e.g., a device, an element, a circuit, a wiring, an electrode, a terminal, a conductive film, or a layer).

When this specification and the like explicitly states that X and Y are connected, the case where X and Y are electrically connected, the case where X and Y are functionally connected, and the case where X and Y are directly connected are regarded as being disclosed in this specification and the like. Accordingly, without limitation to a predetermined connection relation, for example, a connection relation shown in drawings or text, another connection relation is regarded as being disclosed in the drawings or the text.

This application is based on Japanese Patent Application Serial No. 2019-121280 filed with Japan Patent Office on Jun. 28, 2019, the entire contents of which are hereby incorporated by reference.

What is claimed is:

1. A functional panel comprising:
a first region;
a second region; and
a third region between the first region and the second region,
wherein the third region is bendable,
wherein the third region comprises a functional layer, a first conductive film, and a bonding layer between the functional layer and the first conductive film,
wherein the functional layer comprises a circuit and an insulating film,
wherein the circuit comprises a second conductive film,
wherein the insulating film is between the first conductive film and the second conductive film, and
wherein the first conductive film and the second conductive film form a capacitor.

2. The functional panel according to claim 1, further comprising a first base,
wherein the first conductive film is between the bonding layer and the first base.

3. The functional panel according to claim 1, further comprising:
a fourth region; and
a fifth region between the first region and the fourth region,
wherein the fifth region has a first flexural rigidity,
wherein the third region comprises a second base,
wherein the first conductive film is between the bonding layer and the second base,
wherein the third region has a second flexural rigidity, and
wherein the second flexural rigidity is higher than the first flexural rigidity.

4. The functional panel according to claim 3,
wherein the third region is bent such that the first conductive film is on the outer side than the functional layer, with the center of a circle of curvature that appears at the bending as the reference, and
wherein the fifth region is bendable in a direction opposite to a bending direction of the third region.

5. The functional panel according to claim 1, further comprising a first pixel,
wherein the circuit comprises a first pixel circuit,
wherein the first pixel comprises a light-emitting element and the first pixel circuit, and
wherein the light-emitting element is electrically connected to the first pixel circuit.

6. The functional panel according to claim 5, further comprising a second pixel,
wherein the second pixel comprises a second pixel circuit and a photoelectric conversion element, and
wherein the photoelectric conversion element is electrically connected to the second pixel circuit.

7. The functional panel according to claim 6,
wherein the functional layer comprises the first pixel circuit,
wherein the first pixel circuit comprises a first transistor,
wherein the functional layer comprises the second pixel circuit,
wherein the second pixel circuit comprises a second transistor,
wherein the functional layer comprises a driver circuit,
wherein the driver circuit comprises a third transistor,
wherein the first transistor comprises a semiconductor film,
wherein the second transistor comprises a semiconductor film that is formed in a step of forming the semiconductor film of the first transistor, and
wherein the third transistor comprises a semiconductor film that is formed in the step of forming the semiconductor film of the first transistor.

8. A display device comprising:
the functional panel according to claim 5; and
a control portion,
wherein the control portion is supplied with image data and control data.
wherein the control portion generates data on the basis of the image data,
wherein the control portion generates a control signal on the basis of the control data,
wherein the control portion supplies the data and the control signal,
wherein the functional panel is supplied with the data and the control signal, and
wherein the first pixel emits light on the basis of the data.

9. An input/output device comprising:
an input portion; and
a display portion,
wherein the display portion comprises the functional panel according to claim 5,
wherein the input portion comprises a sensing region,
wherein the input portion senses an object approaching the sensing region, and
wherein the sensing region comprises a region overlapping with the first pixel.

10. A data processing device comprising:
an arithmetic device; and
an input/output device,
wherein the arithmetic device is supplied with input data or sensing data,
wherein the arithmetic device generates control data and image data on the basis of the input data or the sensing data,
wherein the arithmetic device supplies the control data and the image data,
wherein the input/output device supplies the input data and the sensing data,
wherein the input/output device is supplied with the control data and the image data,
wherein the input/output device comprises a display portion, an input portion, and a sensor portion,
wherein the display portion comprises the functional panel according to claim 5,
wherein the display portion displays the image data on the basis of the control data,
wherein the input portion generates the input data, and
wherein the sensor portion generates the sensing data.

11. A data processing device comprising:
the functional panel according to claim 5; and
at least one of a keyboard, a hardware button, a pointing device, a touch sensor, an illuminance sensor, an imaging device, an audio input device, an eye-gaze input device, and an attitude sensing device.

12. A semiconductor device comprising:
a housing; and
a functional panel comprising a first region, a second region, and a third region between the first region and the second region,
wherein the third region is bendable,
wherein the third region comprises a functional layer, a first conductive film, and a bonding layer between the functional layer and the first conductive film,
wherein the functional layer comprises a circuit and an insulating film,
wherein the circuit comprises a second conductive film,
wherein the insulating film is between the first conductive film and the second conductive film,
wherein the first conductive film and the second conductive film form a capacitor,
wherein the housing comprises a first plane, a second plane, and a third plane between the first plane and the second plane,
wherein the first plane and the first region overlap with each other,
wherein the second plane and the second region overlap with each other,
wherein a distance is provided between the third plane and the third region, and
wherein the distance is changed by bending of the third region.

13. The semiconductor device according to claim 12, further comprising a first base,
wherein the first conductive film is between the bonding layer and the first base.

14. The semiconductor device according to claim 12, further comprising:
a fourth region; and
a fifth region between the first region and the fourth region,
wherein the fifth region has a first flexural rigidity,
wherein the third region comprises a second base,
wherein the first conductive film is between the bonding layer and the second base,
wherein the third region has a second flexural rigidity, and
wherein the second flexural rigidity is higher than the first flexural rigidity.

15. The semiconductor device according to claim 14,
wherein the third region is bent such that the first conductive film is on the outer side than the functional layer, with the center of a circle of curvature that appears at the bending as the reference, and
wherein the fifth region is bendable in a direction opposite to a bending direction of the third region.

16. The semiconductor device according to claim 12, further comprising a first pixel,
wherein the circuit comprises a first pixel circuit,
wherein the first pixel comprises a light-emitting element and the first pixel circuit, and
wherein the light-emitting element is electrically connected to the first pixel circuit.

17. The semiconductor device according to claim 16, further comprising a second pixel,
wherein the second pixel comprises a second pixel circuit and a photoelectric conversion element, and
wherein the photoelectric conversion element is electrically connected to the second pixel circuit.

18. The semiconductor device according to claim 17,
wherein the functional layer comprises the first pixel circuit,
wherein the first pixel circuit comprises a first transistor,
wherein the functional layer comprises the second pixel circuit,
wherein the second pixel circuit comprises a second transistor,
wherein the functional layer comprises a driver circuit,
wherein the driver circuit comprises a third transistor,
wherein the first transistor comprises a semiconductor film,
wherein the second transistor comprises a semiconductor film that is formed in a step of forming the semiconductor film of the first transistor, and
wherein the third transistor comprises a semiconductor film that is formed in the step of forming the semiconductor film of the first transistor.
